(19) United States
(12) Patent Application Publication
(10) Pub. No.: US 2026/0130279 A1
(43) Pub. Date: May 7, 2026

(54) SEMICONDUCTOR DEVICE AND METHODS OF FORMATION

(71) Applicant: Taiwan semiconductor Manufacturing Company, Ltd., Hsinchu (TW)

(72) Inventors: Tzu Jung TIEN, Hsinchu County (TW); Jen-Yuan CHANG, Hsinchu City (TW)

(21) Appl. No.: 18/937,375

(22) Filed: Nov. 5, 2024

(51) Int. Cl. H01L 23/00; H01L 25/00; H01L 25/065

(52) U.S. Cl. CPC H10W 90/00; H10W 72/01951; H10W 72/01953; H10W 72/823; H10W 72/921; H10W 72/923; H10W 80/211; H10W 80/312; H10W 80/327; H10W 90/231; H10W 90/792

(57) ABSTRACT

A first integrated circuit (IC) die and a second IC die are bonded together in a stacked arrangement in a device package. The second IC die includes at least one bonding structure that is bonded to the first IC die. A barrier layer on sidewalls of a top portion of the bonding structure is removed and replaced with a dielectric liner that is formed on the sidewalls after the bonding structure is formed. The dielectric liner has a material removal rate (e.g., for processes such as CMP, grinding, and/or chemical-based surface cleaning) that is closer to the material removal rate of the bonding structure than the material removal rate of the barrier liner. This reduces the likelihood of the formation of voids in the bond between the first IC die and the second IC die that might otherwise occur due to excessive material removal from the bonding structure.

### BACKGROUND

A semiconductor die package may include a plurality of integrated circuit (IC) dies that offer a variety of functionalities. Examples of IC dies include a system-on-chip (SoC) IC die, a dynamic random access memory (DRAM) IC die, a logic IC die, and/or a high bandwidth memory (HBM) IC die, among other examples. Some semiconductor die packages include an interposer that enables IC dies to be laterally arranged on the interposer. In some semiconductor die packages, IC dies are vertically arranged using three-dimensional (3D) packaging techniques such as direct bonding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example of a semiconductor die package described herein.

FIGS. 2A-2D illustrate example top view shapes for a bonding pad described herein.

FIGS. 3A-3H are diagrams of an example implementation of forming an integrated circuit (IC) die described herein.

FIGS. 4A-4K are diagrams of an example implementation of forming an IC die described herein.

FIGS. 5A-5H are diagrams of an example implementation of forming a semiconductor die package described herein.

FIGS. 6-9 illustrate example implementations of bonding arrangements for bonding a bonding pad of an IC die to another IC die in a semiconductor die package described herein.

FIG. 10 is a flowchart of an example process associated with forming a semiconductor device described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To enable signals and/or power to be routed between a first integrated circuit (IC) die and a second IC die that are bonded together in a stacked arrangement in a device package, one or more through-substrate interconnect structures may be included through a substrate layer of the first IC die. The through-substrate interconnect structure(s) (sometimes referred to as through-silicon vias or through-substrate vias (TSVs)) may extend between, and may be electrically coupled to, conductive structures on a front side and on a back side of the substrate layer. The conductive structure(s) on the back side of the substrate layer coupled to the through-substrate interconnect structure(s) may be bonded with bonding structures (e.g., bonding vias, bonding pads) of the second IC die.

The bonding structures of the second IC die may be formed of a metal material such as copper (Cu). The metal material of the bonding structures may be susceptible to material migration into the surrounding dielectric layers. Therefore, a barrier liner may be included between the bonding structures and the surrounding dielectric layers to prevent, minimize, and/or otherwise reduce the likelihood of migration of material into the surrounding dielectric layers, which might otherwise result in current leakage from the bonding structures.

Barrier liners for material migration blocking are typically formed of hard materials such as tantalum nitride (TaN) and/or titanium nitride (TiN) that are highly resistant to material removal processes such as chemical mechanical planarization (CMP) and grinding. This is in contrast to the softer metal material of the bonding structures, which may have a greater material removal rate for CMP/grinding than the material removal rate of the material of the barrier liner included on sidewalls of the bonding structures. The difference between the material removal rates may result in uneven material removal from the bonding structures and the barrier liner, which may result in the formation of voids between the barrier liner and the bonding structures because of excessive material removal from the bonding structures. These voids may lead to weak electrical connections (or disconnections) between the bonding structures and the through-substrate interconnect structure(s) (which may reduce the electrical performance of the device package) and/or may lead to reduced mechanical strength in the bonds between the bonding structures and the through-substrate interconnect structure(s) (which may increase the likelihood of delamination between the first IC die and the second IC die).

In some implementations described herein, a first IC die and a second IC die are bonded together in a stacked arrangement in a device package. The second IC die includes at least one bonding structure that is bonded to the first IC die. The bonding structure is formed in a manner such that a barrier layer is omitted from the sidewalls of a top portion of the bonding structure. The barrier layer is removed and replaced with a dielectric liner that is formed on the sidewalls after the bonding structure is formed.

The dielectric liner has a material removal rate (e.g., for processes such as CMP, grinding, and/or chemical-based surface cleaning) that is closer to the material removal rate of the bonding structure than the material removal rate of the barrier liner. This reduces the likelihood of the formation of voids in the bond between the first IC die and the second IC die that might otherwise occur due to excessive material removal from the bonding structure.

In this way, the removal of the barrier liner from around the top portion of the bonding structure enables strong electrical connections to be formed between the bonding structure and the first IC die, which may increase the electrical performance of the device package in that electrical resistance and/or power consumption of the device package may be reduced.

Additionally and/or alternatively, the removal of the barrier liner from around the top portion of the bonding structure enables increased mechanical strength to be achieved for the bonds between the bonding structure and the first IC die, which may reduce the likelihood of delamination between the first IC die and the second IC die.

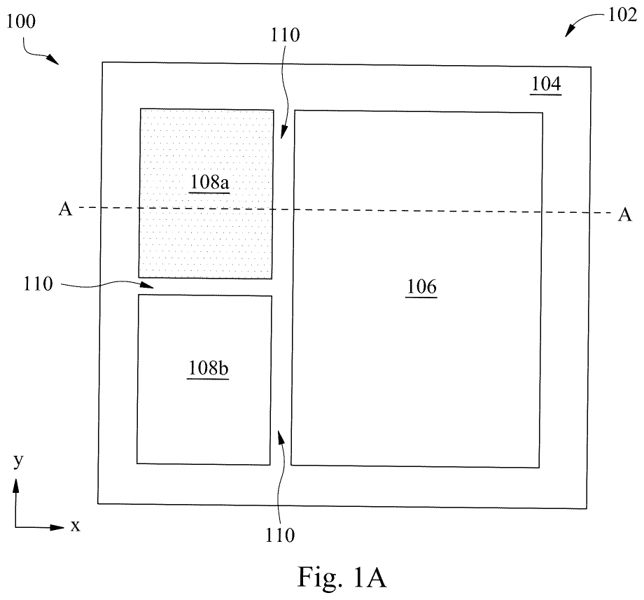

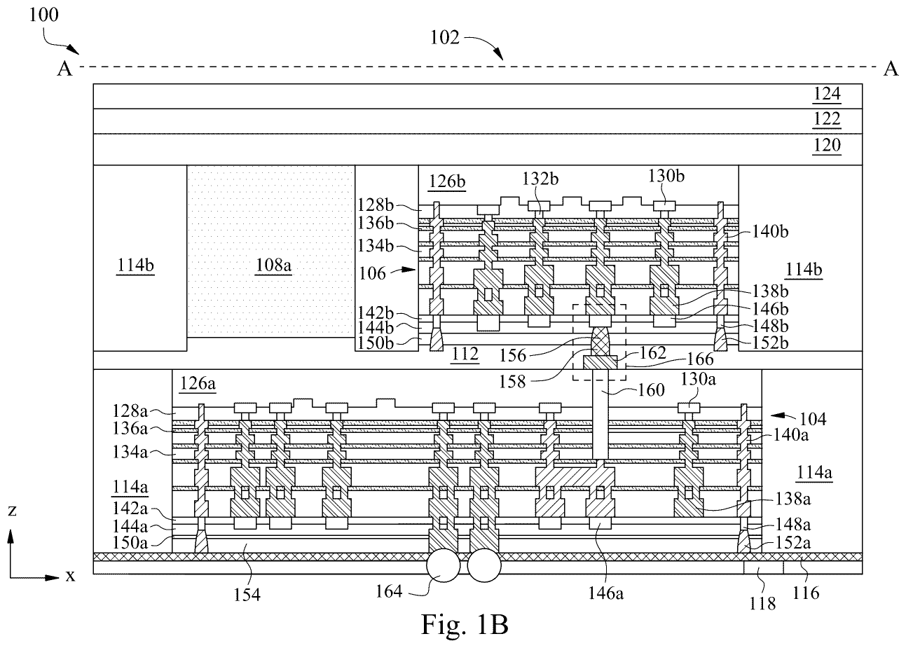

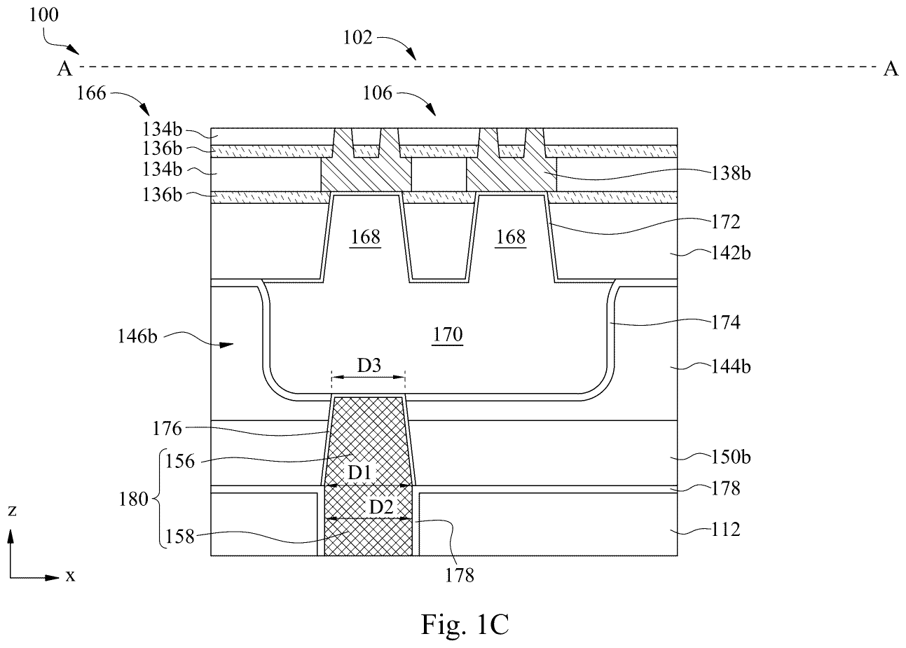

FIGS. 1A-1C are diagrams of an example 100 of a semiconductor die package 102 described herein. The semiconductor die package 102 includes a packaged semiconductor device that includes a plurality of active IC dies or chips. The plurality of active IC dies may be vertically arranged and/or stacked in the semiconductor die package 102 using three-dimensional (3D) packaging techniques such as direct bonding.

FIG. 1A illustrates a top view of the semiconductor die package 102. As shown in FIG. 1A, the semiconductor die package 102 includes an IC die 104. The IC die 104 is an IC die that includes active integrated circuits of the semiconductor die package 102 and is configured perform various processing functions of the semiconductor die package 102. Examples for the IC die 104 includes a logic IC die, a memory IC die, a high-bandwidth memory (HBM) IC die, an input/output (I/O) die, a system-on-chip (SoC) IC die, a dynamic random access memory (DRAM) IC die, a complementary metal-oxide-semiconductor (CMOS) image sensor IC die, a silicon photonics IC die, a central processing unit (CPU) IC die, a graphics processing unit (GPU) IC die, a digital signal processing (DSP) IC die, an application specific integrated circuit (ASIC) IC die, and/or another type of active IC die.

As further shown in FIG. 1A, the semiconductor die package 102 further includes an IC die 106. The IC die 106 is included on the IC die 104 such that the IC dies 104 and 106 are stacked and vertically arranged in a z-direction in the semiconductor die package 102. In some implementations, the IC die 104 and the IC die 106 are the same type of active IC die. For example, the IC die 104 and the IC die 106 may each be a separate CPU die. In some implementations, the IC die 104 and the IC die 106 are different types of active IC dies. For example, the IC die 104 may be a CPU die, and the IC die 106 may be an I/O die or an HBM die.

As further shown in FIG. 1A, the top view area of the IC die 106 may be different from the top view area of the IC die 104. For example, the top view size of the IC die 104 (e.g., the size of the x-y area occupied by the IC die 104) may be greater than the top view size of the IC die 106 (e.g., the size of the x-y area occupied by the IC die 106). Alternatively, the top view area of the IC die 104 and the top view area of the IC die 106 may be approximately the same.

In implementations in which the IC dies 104 and 106 have different top view areas, one or more non-active dies 108a and/or 108b may be included over and/or on the IC die 104 over regions of the IC die 104 that extend laterally outward from the IC die 106. The non-active dies 108a and/or 108b may each include dies that are passive components and/or dies that do not perform electrical and/or processing functions of the semiconductor die package 102. Examples of non-active dies 108a and/or 108b include dummy dies, integrated passive device (IPD) dies, dielectric structures (e.g., thick films), and/or other types of non-active dies. A non-active die may also be referred to as an insertion die, a filler die, and/or another type of die that does not perform electrical and/or processing functions of the semiconductor die package 102. An IPD die may include a capacitor or capacitor die, a resistor or resistor die, an inductor or inductor die, or a combination thereof.

The non-active dies 108a and the IC die 106 may be physically touching (e.g., in physical contact with each other) or may be spaced apart by a gap 110. The non-active die 108b and the IC die 106 may be physically touching (e.g., in physical contact with each other) or may be spaced apart by a gap 110. In some implementations, the non-active dies 108a and 108b may be physically touching (e.g., in physical contact with each other) or may be spaced apart by a gap 110.

FIG. 1B illustrates a cross-section view of the semiconductor die package 102 along the line A-A in FIG. 1A. Thus, the cross-section view illustrated in FIG. 1B includes the IC die 104, the IC die 106 over and/or on the IC die 104, and the non-active die 108a over and/or on the IC die 104 and laterally adjacent to the IC die 106. Alternatively, the non-active die 108a may be omitted.

As shown in FIG. 1B, the IC dies 104 and 106 are bonded together at a bonding dielectric layer (or bonding film) 112. The bonding dielectric layer 112 includes one or more types of materials such as a silicon oxide (SiOₓ) (e.g., silicon dioxide (SiO₂)) and/or another type of dielectric bonding material. The IC dies 104 and 106 may be directly bonded (e.g., without an intervening interposer or another intervening structure) such that the IC dies 104 and 106 are stacked and vertically arranged in the z-direction in the semiconductor die package 102.

As further shown in FIG. 1B, the areas around the sides of the IC die 104 are filled with a dielectric fill layer 114a such that the dielectric fill layer 114a surrounds the IC die 104, and the areas around the sides of the IC die 106 and the non-active die 108a (including the gaps 110) are filled with a dielectric fill layer 114b such that the dielectric fill layer 114b surrounds the IC die 106. The dielectric fill layer 114b may further surround the non-active dies 108a and 108b. The dielectric fill layers 114a and 114b may each include one or more dielectric materials such as a silicon oxide (SiOₓ) (e.g., silicon dioxide (SiO₂)), silicon oxynitride (SiON), and/or another type of dielectric material. The dielectric fill layers 114a and 114b may provide increased stability and electrical isolation for the IC dies 104 and 106.

The semiconductor die package 102 includes a plurality of passivation layers, including passivation layers 116 and 118 over and/or on a bottom side of the semiconductor die package 102, and passivation layers 120, 122, and 124 over and/or on a top side of the semiconductor die package 102, among other examples. In some implementations, the passivation layers 116, 118, 120, 122, and 124 may each include various types of electrically insulating materials, such as a silicon nitride (SiₓN_{y}), an undoped silicate glass (USG), a silicon oxide (SiOₓ) (e.g., silicon dioxide (SiO₂)), and/or another type of passivation material.

The IC dies 104 and 106 may each include a substrate (e.g., substrate 126a in the IC die 104 and substrate 126b in the IC die 106). The substrates 126a and 126b may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The IC dies 104 and 106 may each include a plurality of stacked layers, including an interlayer dielectric (ILD) layer (e.g., an ILD layer 128a on the substrate 126a and an ILD layer 128b on the substrate 126b). The ILD layers 128a and 128b may each include a silicon nitride (SiₓN_{y}), an oxide (e.g., a silicon oxide (SiOₓ) and/or another oxide material), and/or another type of dielectric material.

The IC dies 104 and 106 may each include IC devices (e.g., IC devices 130a in the substrate 126a and/or in the ILD layer 128a, IC devices 130b in the substrate 126b and/or in the ILD layer 128b). The IC devices 130a and 130b may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices.

The IC dies 104 and 106 may each include contacts (e.g., contacts 132a, contacts 132b) that are electrically coupled with the IC devices. The contacts 132a may extend through the ILD layer 128a and may be electrically coupled with the IC devices 130a, and the contacts 132b may extend through the ILD layer 128b and may be electrically coupled with the IC devices 130b. The contacts 132a and 132b may include vias, plugs, and/or another type of elongated electrically conductive structures. The contacts 132a and 132b may include tungsten (W), cobalt (Co), ruthenium (Ru), titanium (Ti), aluminum (Al), and/or gold (Au), among other electrically conductive materials.

The IC dies 104 and 106 may each include a plurality of dielectric layers that are arranged in an alternating manner in the z-direction in the semiconductor die package 102. For example, the IC die 104 may include a plurality of alternating ILD layers 134a and etch stop layers (ESLs) 136a. The IC die 104 may include a plurality of conductive structures 138a in the ILD layers 134a and ESLs 136a. The substrate 126a, the ILD layer 128a, the IC devices 130a, and the contacts 132a may correspond to a device layer or front end of line (FEOL) region of the IC die 104, and the ILD layers 134a, the ESLs 136a, and the conductive structures 138a may correspond to an interconnect layer or back end of line (BEOL) region of the IC die 104.

Similarly, the IC die 106 may include a plurality of alternating ILD layers 134b and ESLs 136b. The IC die 106 may include a plurality of conductive structures 138b in the ILD layers 134b and ESLs 136b. The substrate 126b, the ILD layer 128b, the IC devices 130b, and the contacts 132b may correspond to a device layer or FEOL region of the IC die 106, and the ILD layers 134b, the ESLs 136b, and the conductive structures 138b may correspond to an interconnect layer or BEOL region of the IC die 106.

The ILD layers 134a and 134b may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 134a or 134b includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. The ESLs 136a and 136b may each include a silicon nitride (SiₓN_{y}), silicon carbide (SiC), silicon oxynitride (SiON), and/or another suitable dielectric material.

The conductive structures 138a and 138b provide electrical routing that enables signals and/or power to be provided to and/or from the IC devices 130a and/or 130b. The conductive structures 138a and 138b may include a combination of trenches, metallization layers, conductive traces, vias, interconnects, and/or other types of conductive structures. The conductive structures 138a and 138b may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The IC die 104 may further include a seal ring structure 140a around the conductive structures 138a to protect the IC die 104 from physical and/or electrical damage during a dicing operation to cut the IC die 104 from a wafer. The seal ring structure 140a may further provide protection from humidity ingress and other contaminants. The IC die 106 may similarly include a seal ring structure 140b around the conductive structures 138b to protect the IC die 106 from physical and/or electrical damage during a dicing operation to cut the IC die 106 from a wafer. The seal ring structure 140b may further provide protection from humidity ingress and other contaminants.

The IC die 104 may include passivation layers 142a and 144a over and/or on the plurality of alternating dielectric layers (e.g., the ILD layers 134a and the ESLs 136a) to passivate the interconnect layer of the IC die 104. Similarly, the IC die 106 may include passivation layers 142b and 144b over and/or on the plurality of alternating dielectric layers (e.g., the ILD layers 134b and the ESLs 136b) to passivate the interconnect layer of the IC die 106.

Metal pad structures 146a may be included over and/or on the conductive structures 138a, and metal pad structures 148a may be included over and/or on the seal ring structure 140a. Metal pad structures 146b may be included over and/or on the conductive structures 138b, and metal pad structures 148b may be included over and/or on the seal ring structure 140b. The metal pad structures 146a and 148a may be included in, and may extend through, the passivation layers 142a and/or 144a. The metal pad structures 146b and 148b may be included in, and may extend through, the passivation layers 142b and/or 144b.

The metal pad structures 146a, 148a, 146b, and 148b may each include aluminum (Al), aluminum copper (AlCu), copper (Cu), and/or another conductive material. The metal pad structures 146a and 148a may correspond to a redistribution layer (RDL) of the IC die 104, and the metal pad structures 146b and 148b may correspond to an RDL of the IC die 106.

A dielectric layer 150a may be included over the passivation layer 144a, and a dielectric layer 150b may be included over the passivation layer 144b. The dielectric layers 150a and 150b may be capping layers and may include one or more dielectric layers such a silicon oxide (SiOₓ such as SiO₂), a silicon nitride (SiₓN_{y} such as Si₃N₄), a silicon oxynitride (SiON), a silicon oxycarbide (SiOC), and/or a silicon carbonitride (SiCN), among other examples. The bonding dielectric layer 112 of the IC die 106 may be included over the dielectric layer 150b.

The seal ring structures 140a and 140b may further include bonding pads 152a and 152b, respectively. Alternatively, the bonding pads 152a and/or 152b may be omitted. The bonding pads 152a and 152b may each include tungsten (W), cobalt (Co), ruthenium (Ru), titanium (Ti), aluminum (Al), copper (Cu), gold (Au), and/or a combination thereof, among other examples of electrically conductive materials.

The IC die 104 further includes a bonding layer 154, which is used to bond the IC die 104 to a carrier substrate during manufacturing of the semiconductor die package 102. The bonding layer 154 includes one or more types of materials such as a silicon oxide (SiOₓ) (e.g., silicon dioxide (SiO₂)) and/or another type of dielectric bonding material.

The IC die 106 may further include one or more bonding vias 156 and/or one or more bonding pads 158 that enable the IC die 106 to be bonded to the IC die 104. The bonding vias 156 and/or the bonding pads 158 may extend through the bonding dielectric layer 112, the dielectric layer 150b, and/or the passivation layer 144b and may be electrically coupled and/or physically coupled to one or more metal pad structures 146b. The bonding vias 156 and the bonding pads 158 may each include tungsten (W), cobalt (Co), ruthenium (Ru), titanium (Ti), aluminum (Al), copper (Cu), gold (Au), and/or a combination thereof, among other examples of electrically conductive materials.

In some implementations, a bonding via 156 and/or a bonding pad 158 of the IC die 106 may be electrically coupled to a through-substrate interconnect structure 160 that extends through the substrate 126a of the IC die 104. The through-substrate interconnect structure 160 may include a die-to-die wire, a through substrate via (TSV), or another type of die-to-die interconnect. The through-substrate interconnect structure 160 also electrically connects the IC dies 104 and 106. In this way, electrical signals and/or power may be provided between the IC dies 104 and 106 through the through-substrate interconnect structure 160.

The through-substrate interconnect structure 160 includes a conductive material such as tungsten (W), cobalt (Co), ruthenium (Ru), titanium (Ti), aluminum (Al), copper (Cu), gold (Au), and/or a combination thereof, among other examples of conductive materials. The through-substrate interconnect structure 160 may include a via, a pillar, a column, and/or another type of elongated conductive structure that extends between a front side of the substrate 126a of the IC die 104 (the side of the substrate 126a on which the conductive structures 138a are included) and a back side of the substrate 126a of the IC die 104 vertically opposing the front side. The back side of the IC die 104 may be bonded to the IC die 106, and a bonding pad 162 on the back side of the IC die 104 may be bonded to a bonding pad 158 of the IC die 106.

As further shown in FIG. 1B, a topmost layer of conductive structures 138a (e.g., a top metal layer) of the IC die 104 may be coupled to connection structures 164 at the top of the semiconductor die package 102 (which is facing downward in FIG. 1B). The connection structures 164 may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures that enable the semiconductor die package 102 to be connected to a substrate or a socket, among other examples.

FIG. 1C illustrates a close-up view of a portion 166 of the IC die 106 illustrated in FIG. 1B. As shown in FIG. 1C, a bonding metal structure 146b may include one or more via portions 168 that extend through the passivation layer 142b, and a trench portion 170 included in the passivation layer 144b. A barrier liner 172 may be included between the via portions 168 and the passivation layer 142b. The barrier liner 172 may include tantalum (Ta), tantalum nitride (TaN), titanium (Ti), titanium nitride (TiN), and/or another layer that inhibits migration of material from the via portions 168 into the passivation layer 142b. In some implementations, the barrier liner 172 is included between the via portions 168 and a topmost conductive structure 138b. In some implementations, the barrier liner 172 is omitted from the interface between the via portions 168 and the topmost conductive structure 138b, and the via portions 168 are in physical contact with the topmost conductive structure 138b.

A dielectric liner 174 may be included on sidewalls and on a top surface of the trench portion 170 of the metal pad structure 146b. The dielectric liner 174 may be included between the trench portion 170 and the passivation layer 144b. The dielectric liner 174 may include a silicon oxide (SiOₓ such as SiO₂), a silicon nitride (SiₓN_{y} such as Si₃N₄), a silicon oxynitride (SiON), a silicon oxycarbide (SiOC), and/or a silicon carbonitride (SiCN), among other examples.

As further shown in FIG. 1C, a bonding via 156 may be vertically adjacent (e.g., in the z-direction) to the metal pad structure 146b and may be coupled to the trench portion 170 of the metal pad structure 146b. The bonding via 156 may extend through the dielectric layer 150b and into the passivation layer 144b to the metal pad structure 146b. A barrier liner 176 may be included on the sidewalls of the bonding via 156 between the bonding via 156 and the dielectric layer 150b. In some implementations, the barrier liner 176 is also included between the bottom of the bonding via 156 and the trench portion 170 of the metal pad structure 146b. In some implementations, the barrier liner 176 is omitted from the bottom of the bonding via 156 such that the bonding via 156 is in contact with the trench portion 170 of the metal pad structure 146b.

As further shown in FIG. 1C, a bonding pad 158 may be vertically adjacent (e.g., in the z-direction) to the bonding via 156 and may be electrically coupled and/or physically coupled to the bonding via 156. The bonding pad 158 may be included in and/or may extend through the bonding dielectric layer 112.

A dielectric liner 178 may be included on the sidewalls of the bonding pad 158 instead of the barrier liner 176. During formation of the IC die 106, the bonding pad 158 may be formed on the bonding via 156 such that the barrier liner 176 is in contact with the sidewalls of the bonding pad 158. The barrier liner 176 is subsequently removed from the sidewalls of the bonding pad 158 and replaced with the dielectric liner 178. The dielectric liner 178 may be formed prior to the bonding dielectric layer 112, and may therefore extend along between the dielectric layer 150b and the bonding dielectric layer 112.

The barrier liner 176 may include tantalum (Ta), tantalum nitride (TaN), titanium (Ti), titanium nitride (TiN), and/or another layer that inhibits migration of material from the bonding via 156 into the dielectric layer 150b. The dielectric liner 178 is formed after formation of the bonding pad 158, and therefore the dielectric liner 178 is less susceptible to material migration from the bonding pad 158 in that high-temperature processes (such as a copper reflow anneal) have already performed to form the bonding pad 158 prior to formation of the dielectric liner 178.

The dielectric liner 178 may include a silicon oxide (SiOₓ such as SiO₂), a silicon nitride (SiₓN_{y}such as Si₃N₄), a silicon oxynitride (SiON), a silicon oxycarbide (SiOC), and/or a silicon carbonitride (SiCN), among other examples. The material of the dielectric liner 178 may have a material hardness that is less than the material hardness of the barrier liner 176, and that is closer to the material hardness of the material of the bonding pad 158 than the material of the barrier liner 176. In some implementations, the dielectric liner 178 includes a low dielectric constant (low-k) dielectric material that has a dielectric constant that is less than the dielectric constant of the material of the dielectric liner 178 (e.g., less than the dielectric constant of TaN, less than the dielectric constant of TiN). Low-k dielectric materials tend to have lower material hardnesses than high-k dielectric materials, and therefore, the material removal rate (e.g., for processes such as CMP, grinding, and/or chemical-based surface cleaning) is closer to the material removal rate of the bonding pad 158 than the material removal rate of the barrier liner 176. This reduces the likelihood of dishing and/or crowning that might otherwise occur in the surface of the bonding pad 158, which reduces the likelihood of the formation of voids in the bond between the bonding pad 158 and the IC die 104.

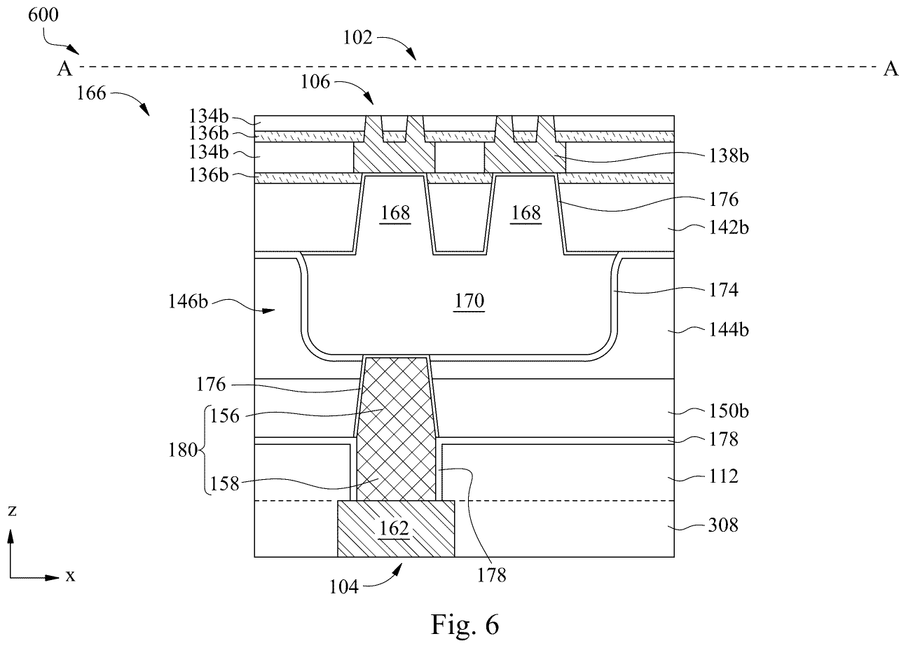

In some implementations, the bonding via 156 and the bonding pad 158 are formed as a singular structure, referred to as a bonding structure 180. The bonding via 156 may correspond to a via portion (or a bottom portion) of the bonding structure 180, and the bonding pad 158 may correspond to a pad portion 158 (or a top portion) of the bonding structure 180. The bonding structure 180 may be a “bonding structure” in that the bonding structure 180 is used to bond the IC die 106 to the IC die 104. Examples of different bond types are illustrated and described in connection with FIGS. 6-9.

As further shown in FIG. 1C, the bonding via 156 may have a top width (e.g., at the top of the bonding via 156) corresponding to a dimension D1, and the bonding pad 158 may have a width corresponding to a dimension D2. In some implementations, the dimension D1 and the dimension D2 are approximately equal. In some implementations, the dimension D2 is greater than the dimension D1, such that the bonding pad 158 extends laterally outward from the sidewalls of the bonding via 156.

In some implementations, the bonding via 156 may have a bottom width (e.g., at the bottom of the bonding via 156) corresponding to a dimension D3. In some implementations, the dimension D1 and the dimension D3 are approximately equal. In some implementations, the dimension D1 is greater than the dimension D3. In some implementations, the maximum value for the dimension D1 is approximately 100,000 times the minimum value for the dimension D1. However, other values and ranges for the dimension D1 are within the scope of the present disclosure.

As indicated above, FIGS. 1A-1C are provided as an example. Other examples may differ from what is described with regard to FIGS. 1A-1C.

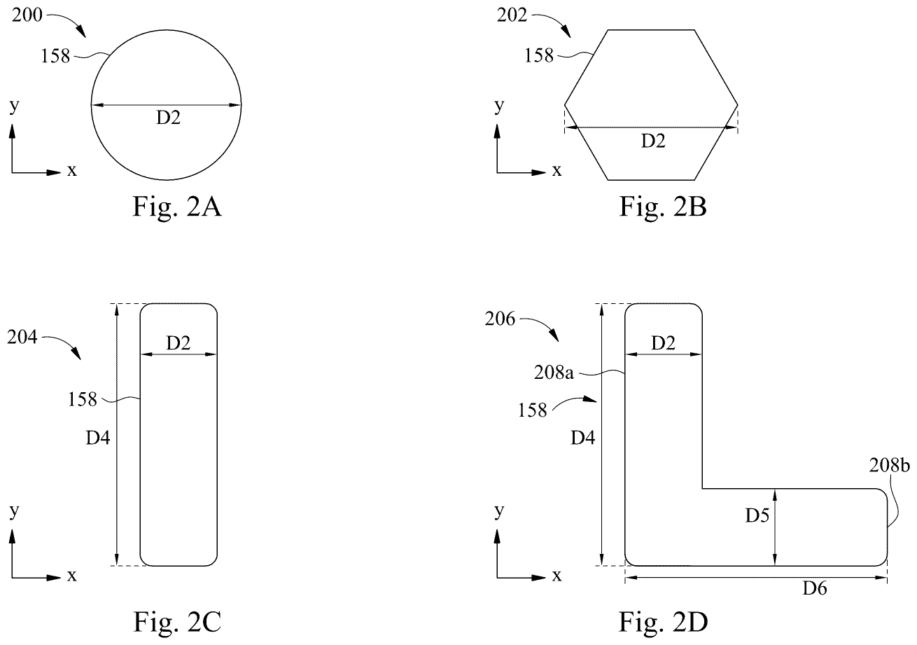

FIGS. 2A-2D illustrate example top view shapes for a bonding pad 158 described herein. While FIGS. 2A-2D provide various examples, other example top view shapes for a bonding pad 158 are within the scope of the present disclosure. Moreover, the IC die 106 may include a plurality of bonding pads 158 that have a combination of example top view shapes.

As shown in FIG. 2A, an example top view shape 200 includes an approximate circle top view shape. The dimension D2 of the bonding pad 158 may correspond to a diameter of the approximate circle top view shape of the bonding pad 158.

As shown in FIG. 2B, an example top view shape 202 includes an approximate hexagon top view shape. The dimension D2 of the bonding pad 158 may correspond to a maximal diameter of the approximate hexagon top view shape of the bonding pad 158.

As shown in FIG. 2C, an example top view shape 204 includes an approximate rectangle top view shape. The dimension D2 of the bonding pad 158 may correspond to a width of the approximate rectangle top view shape of the bonding pad 158 along a short side of the approximate rectangle top view shape, and a dimension D3 of the bonding pad 158 may correspond to a width of the approximate rectangle top view shape of the bonding pad 158 along a long side of the approximate rectangle top view shape.

As shown in FIG. 2D, an example top view shape 206 includes an approximate L-shape having a first top view segment 208a and a second top view segment 208b that are connected together at ends of the top view segments 208a and 208b. The dimension D2 of the bonding pad 158 may correspond to a width of the top view segment 208a along a short side of the top view segment 208a, and the dimension D4 of the bonding pad 158 may correspond to a width of the top view segment 208a along a long side of the top view segment 208a. A dimension D5 of the bonding pad 158 may correspond to a width of the top view segment 208b along a short side of the top view segment 208b, and the dimension D6 of the bonding pad 158 may correspond to a width of the top view segment 208b along a long side of the top view segment 208b.

In some implementations, the dimension D2 and the dimension D5 are approximately equal values. In some implementations, the dimension D2 and the dimension D5 are different values. In some implementations, the dimension D4 and the dimension D6 are approximately equal values. In some implementations, the dimension D4 and the dimension D6 are different values.

As indicated above, FIGS. 2A-2D are provided as examples. Other examples may differ from what is described with regard to FIGS. 2A-2D.

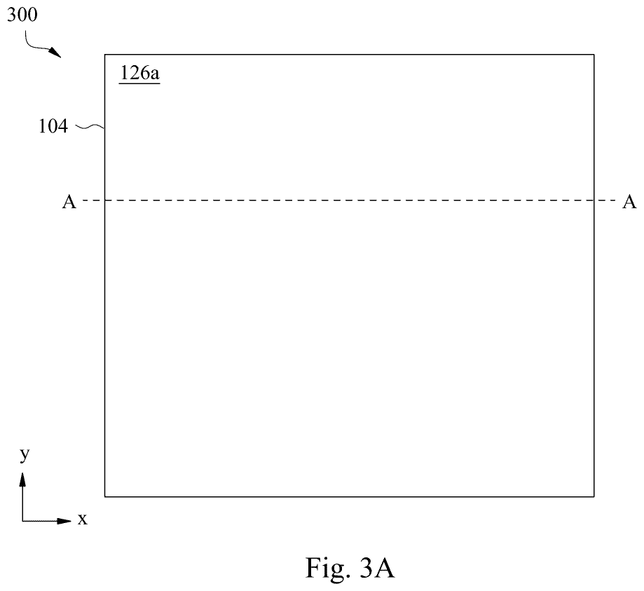

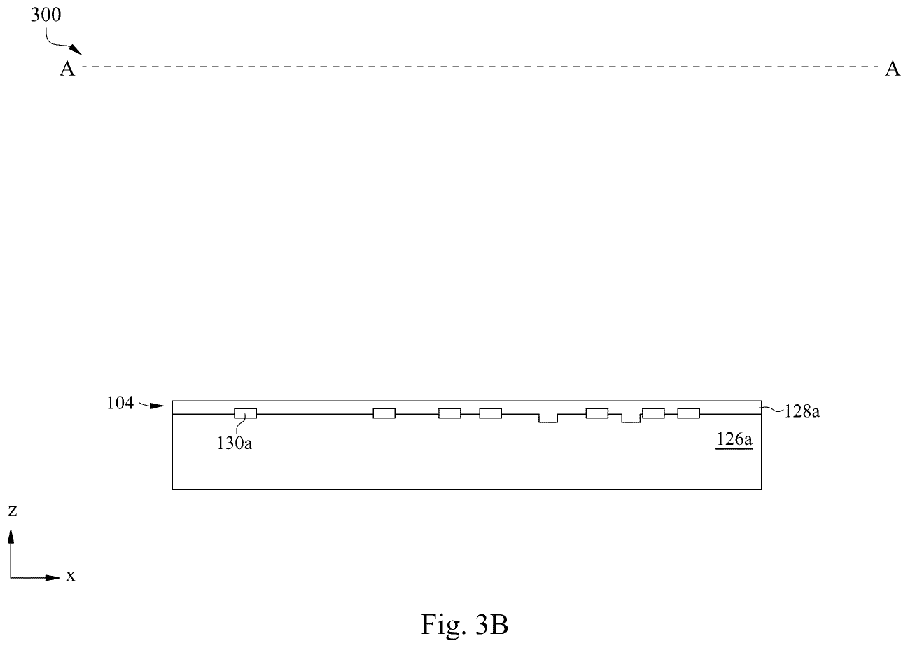

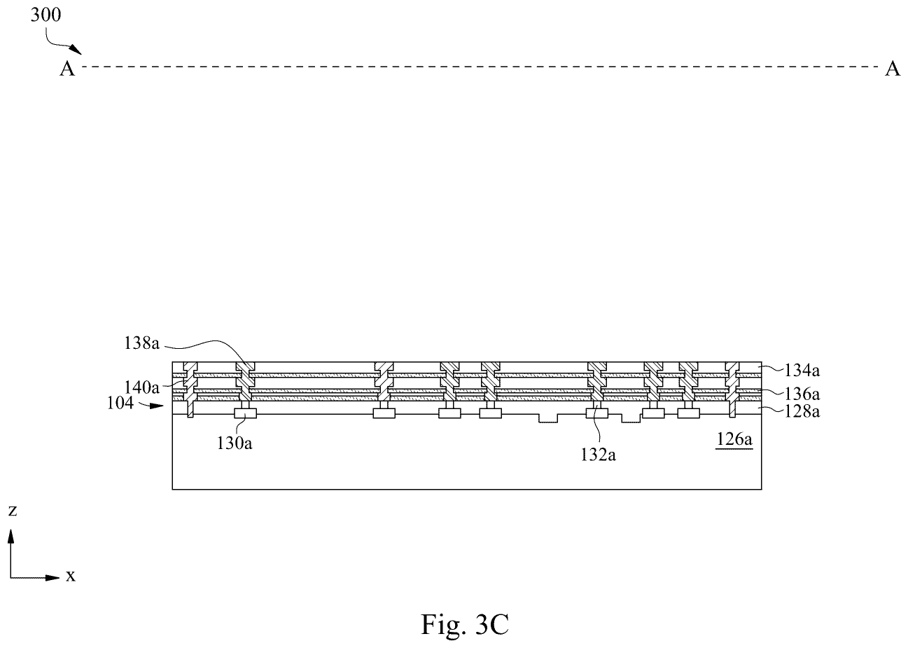

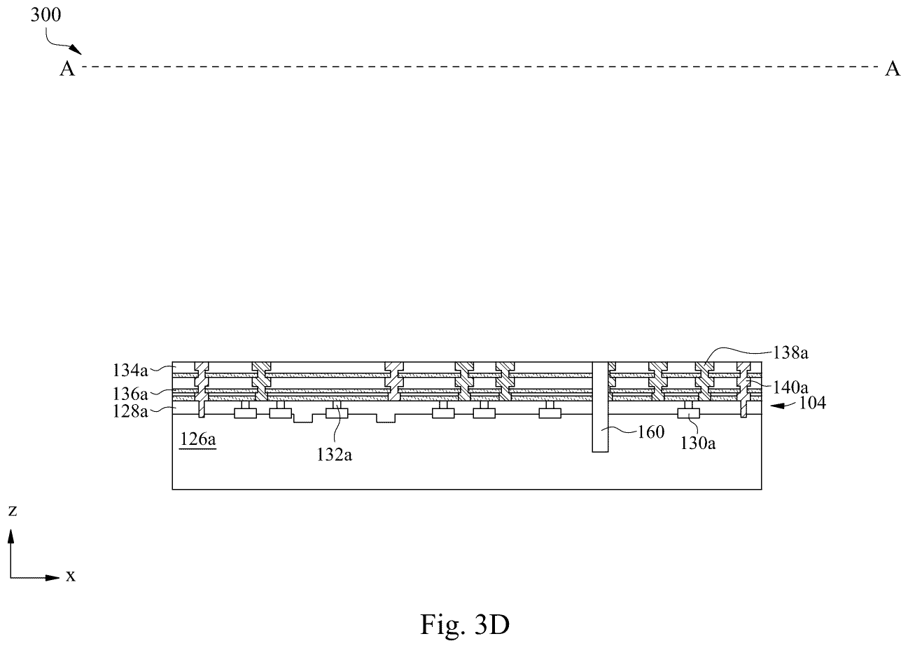

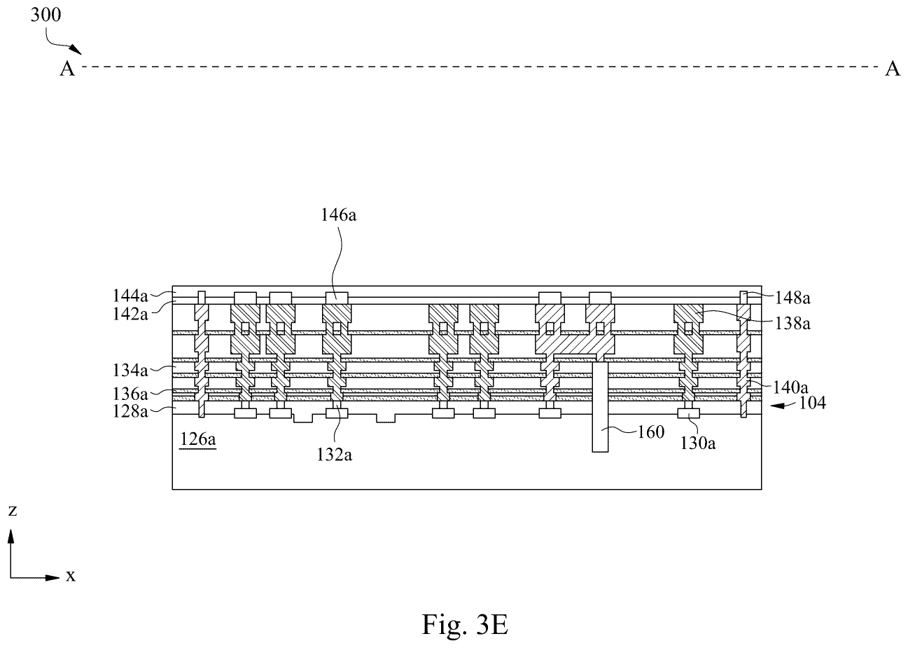

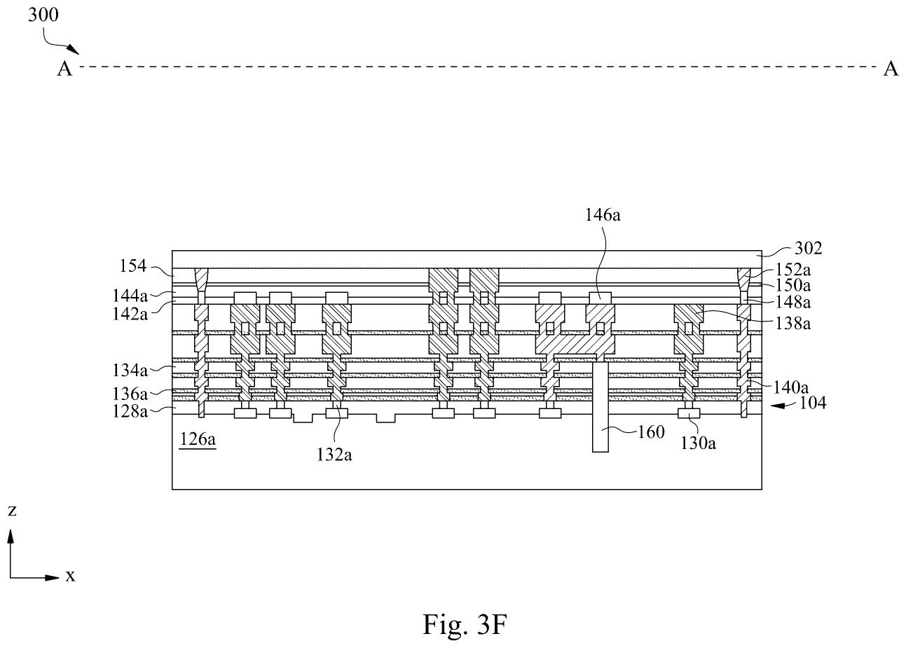

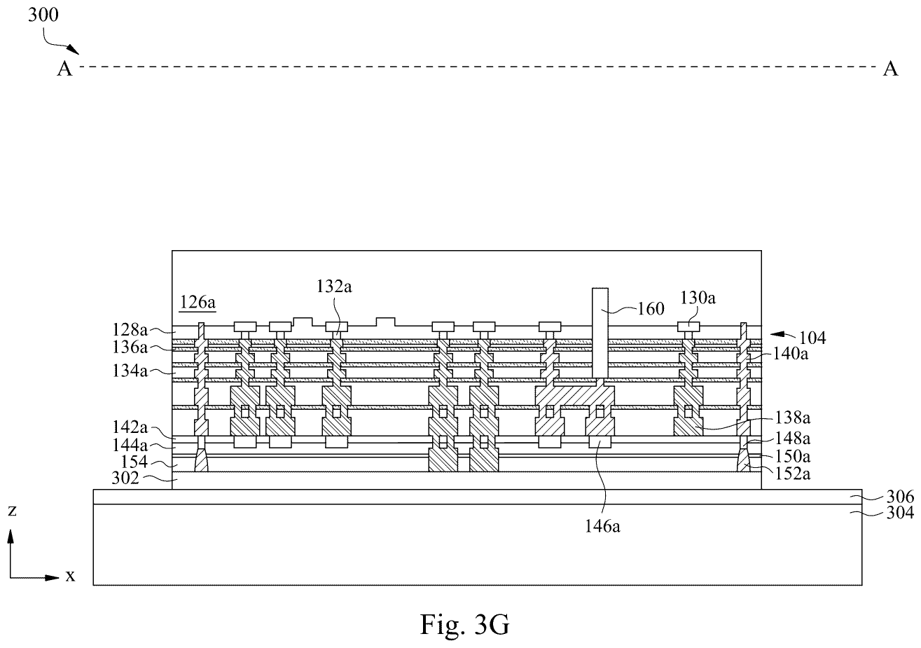

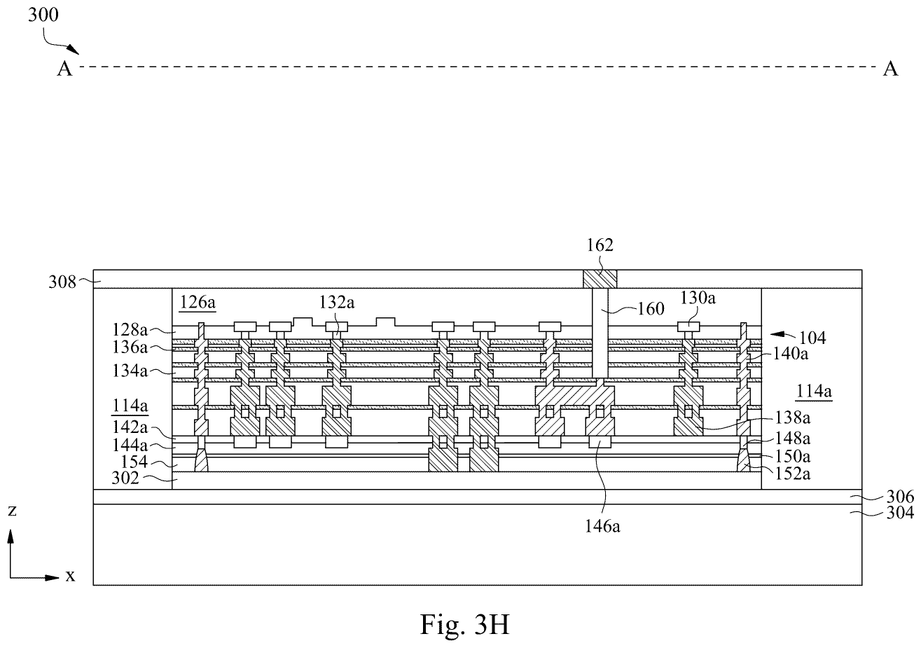

FIGS. 3A-3H are diagrams of an example implementation 300 of forming an IC die described herein. While the processing operations of the example implementation 300 are illustrated and described in connection with forming the IC die 104 described herein, the processing operations of the example implementation 300 may be performed to form another IC die described herein, such as the IC die 106. In some implementations, one or more of the semiconductor processing operations described in connection with FIGS. 3A-3H may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 126a of the IC die 104 is provided. The substrate 126a may be provided in the form of a semiconductor wafer such as a silicon (Si) wafer, may be provided as an SOI wafer, and/or another type of semiconductor work piece.

As shown in FIG. 3B, the IC devices 130a may be formed in and/or on the substrate 126a of the IC die 104. One or more semiconductor processing tools may be used to form one or more portions of the IC devices 130a. For example, a deposition tool may be used to perform various deposition operations to deposit layers and/or structures of the IC devices 130a, and/or to deposit photoresist layers for etching the substrate 126a and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 126a and/or portions of the deposited layers to form the IC devices 130a. As another example, a planarization tool may be used to planarize portions of the IC devices 130a. As another example, a plating tool may be used to deposit metal structures and/or layers of the IC devices 130a.

As further shown in FIG. 3B, a deposition tool is used to deposit the ILD layer 128a over and/or on the substrate 126a and over and/or on the IC devices 130a. A deposition tool may be used to deposit the ILD layer 128a using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the ILD layer 128a after the ILD layer 128a is deposited.

As shown in FIG. 3C, the contacts 132a of the IC devices 130a may be formed through the ILD layer 128a. The contacts 132a may be formed in recesses in the ILD layer 128a. In some implementations, a pattern in a photoresist layer is used to etch the ILD layer 128a to form the recesses. In these implementations, a deposition tool may be used to form the photoresist layer on the ILD layer 128a. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 128a based on a pattern to form the recesses.

A deposition tool may be used to deposit the material of the contacts 132a in the recesses using a CVD technique, a PVD technique, an ALD technique, an electroplating technique, and/or another suitable deposition technique. The material of the contacts 132a may be deposited in one or more deposition operations. In some implementations, a seed layer is first deposited, and the material of the contacts 132a is deposited on the seed layer. In some implementations, a planarization tool is used to perform a planarization operation (e.g., a CMP operation) to planarize the contacts 132a after the contacts 132a are deposited such that the tops of the contacts 132a are approximately co-planar with the top of the ILD layer 128a.

As shown in FIG. 3C, a first portion of the interconnect layer of the IC die 104 is formed above the ILD layer 128a. One or more deposition tools are used to deposit alternating layers of ILD layers 134a and ESLs 136a in the first portion of the interconnect layer of the IC die 104. In this way, the ILD layers 134a and ESLs 136a may be arranged in the z-direction in the IC die 104. One or more deposition tools may be used to deposit each of the ILD layers 134a and each of the ESLs 136a using a PVD technique, an ALD technique, a CVD technique, an oxidation technique, and/or another suitable deposition technique. In some implementations, a planarization tool may be used to planarize the ILD layers 134a and/or the ESLs 136a after the ILD layers 134a and/or the ESLs 136a are deposited.

As further shown in FIG. 3C, a deposition tool, an exposure tool, a developer tool, an etch tool, a planarization tool, a plating tool, and/or another semiconductor processing tool may be used to perform various operations to form the conductive structures 138a and a first portion of the seal ring structure 140a in the first portion of the interconnect layer of the IC die 104. The conductive structures 138a and the first portion of the seal ring structure 140a may be included in the ILD layers 134a and/or in the ESLs 136a.

The conductive structures 138a and the first portion of the seal ring structure 140a may be formed in recesses in one or more ILD layers 134a and/or in one or more ESLs 136a. In some implementations, a pattern in a photoresist layer is used to etch the ILD layers 134a and ESLs 136a to form the recesses. In these implementations, a deposition tool may be used to form the photoresist layer on the topmost ILD layer 134a. An exposure tool may be used to expose the photoresist layer to a radiation source to pattern the photoresist layer. A developer tool may be used to develop and remove portions of the photoresist layer to expose the pattern. An etch tool may be used to etch the ILD layers 134a and ESLs 136a based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layers 134a and ESLs 136a based on a pattern to form the recesses.

A deposition tool may be used to deposit the material of the conductive structures 138a and the first portion of the seal ring structure 140a in the recesses using a CVD technique, a PVD technique, an ALD technique, an electroplating technique, and/or another suitable deposition technique. The material of the conductive structures 138a and the first portion of the seal ring structure 140a may be deposited in one or more deposition operations. In some implementations, a seed layer is first deposited, and the material of the conductive structures 138a and the first portion of the seal ring structure 140a is deposited on the seed layer. In some implementations, a planarization tool is used to perform a planarization operation (e.g., a CMP operation) to planarize the conductive structures 138a and the first portion of the seal ring structure 140a.

As shown in FIG. 3D, the through-substrate interconnect structure 160 is formed through the first portion of the interconnect layer and into the substrate 126a. To form the through-substrate interconnect structure 160, a recess is formed through the first portion of the interconnect layer and into a portion of the substrate 126a.

In some implementations, a pattern in a photoresist layer is used to etch the ILD layers 134a and the ESLs 136a of the first portion of the interconnect layer, the ILD layer 128a, and the substrate 126a to form the recess. In these implementations, a deposition tool may be used to form the photoresist layer on the topmost ILD layer 134a. An exposure tool may be used to expose the photoresist layer to a radiation source to pattern the photoresist layer. A developer tool may be used to develop and remove portions of the photoresist layer to expose the pattern. An etch tool may be used to etch the ILD layers 134a and the ESLs 136a of the first portion of the interconnect layer, the ILD layer 128a, and the substrate 126a based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the through-substrate interconnect structure 160 using a CVD technique, a PVD technique, an ALD technique, an electroplating technique, and/or another suitable deposition technique. The through-substrate interconnect structure 160 may be deposited in one or more deposition operations. In some implementations, a seed layer is first deposited, and the through-substrate interconnect structure 160 is deposited on the seed layer. In some implementations, one or more liners (e.g., a barrier liner, an adhesion liner) may first be deposited in the recess, and the through-substrate interconnect structure 160 may be deposited on the one or more liners in the recess. In some implementations, a planarization tool is used to perform a planarization operation (e.g., a CMP operation) to planarize the through-substrate interconnect structure 160 after the through-substrate interconnect structure 160 is deposited.

As shown in FIG. 3E, a second portion of the interconnect layer of the IC die 104 may be formed. Forming the second portion of the interconnect layer may include forming additional ILD layers 134a, additional ESLs 136a, additional conductive structures 138a, and/or additional portions of the seal ring structure 140a in a similar manner as described in connection with FIG. 3C. As further shown in FIG. 3E, the passivation layer(s) 142a may be deposited, the metal pad structures 146a may be formed on one or more of the conductive structures 138a, and one or more metal pad structures 148a may be formed on the seal ring structure 140a. The passivation layer(s) 144a may be deposited on the passivation layer(s) 142a.

As shown in FIG. 3F, bonding pads 152a may be formed on the metal pad structures 148a. In some implementations, bonding pads may also be formed on one or more conductive structures 138a. Moreover, the dielectric layer 150a may be formed over the passivation layer(s) 144a, and the bonding layer 154 may be formed over the dielectric layer 150a. Another bonding layer 302 may be formed on the bonding layer 154. In some implementations, an ESL is deposited on the bonding layer 154, and the bonding layer 302 is deposited on the ESL.

A deposition tool may be used to deposit the bonding pads 152a using a CVD technique, a PVD technique, an ALD technique, an electroplating technique, and/or another suitable deposition technique. The bonding pads 152a may be deposited in one or more deposition operations. In some implementations, a seed layer is first deposited, and the bonding pads 152a are deposited on the seed layer. In some implementations, one or more liners (e.g., a barrier liner, an adhesion liner) may first be deposited in the recess, and the bonding pads 152a may be deposited on the one or more liners in the recess. In some implementations, a planarization tool is used to perform a planarization operation (e.g., a CMP operation) to planarize the bonding pads 152a after the bonding pads 152a are deposited.

A deposition tool may be used to deposit the dielectric layer 150a and the bonding layers 154, 302 using a PVD technique, an ALD technique, a CVD technique, an oxidation technique, and/or another suitable deposition technique. The dielectric layer 150a and the bonding layers 154, 302 may be deposited in one or more deposition operations. In some implementations, a planarization tool may be used to perform a planarization operation (e.g., a CMP operation) to planarize the dielectric layer 150a and the bonding layers 154, 302 after the dielectric layer 150a and the bonding layers 154, 302 are deposited.

As shown in FIG. 3G, the IC die 104 is bonded to a carrier substrate 304 using the bonding layers 302 and 306. Accordingly, the IC die 104 may be flipped or rotated 180 degrees to bond the IC die 104 to the carrier substrate 304. Moreover, a bonding layer 306 (e.g., a fusion bonding layer or another type of bonding layer) included on the carrier substrate 304 is used to bond the IC die 104 and the carrier substrate 304. A bonding tool may be used to bond the IC die 104 to the carrier substrate 304 using a fusion bonding technique and/or another bonding technique.

As shown in FIG. 3H, areas around the IC die 104 are filled with the dielectric fill layer 114a. A deposition tool may be used to deposit the dielectric fill layer 114a using a PVD technique, an ALD technique, a CVD technique, an oxidation technique, and/or another suitable deposition technique. The dielectric fill layer 114a may be deposited in one or more deposition operations.

As further shown in FIG. 3H, a planarization tool or wafer grinding tool may be used to perform a planarization operation (e.g., a CMP operation, a wafer grinding operation) to planarize the dielectric fill layer 114a and to remove material from the back side of the substrate 126a such that the through-substrate interconnect structure 160 is exposed through the back side of the substrate 126a.

As further shown in FIG. 3H, a bonding dielectric layer 308 is formed over and/or on the back side of the substrate 126a of the IC die 104. A deposition tool may be used to deposit the bonding dielectric layer 112 using a PVD technique, an ALD technique, a CVD technique, an oxidation technique, and/or another suitable deposition technique. In some implementations, planarization tool is used to perform a planarization operation (e.g., a CMP operation,) to planarize the bonding dielectric layer 112.

As further shown in FIG. 3H, a deposition tool may be used to deposit the bonding pads 162 on the back side of the substrate 126a using a CVD technique, a PVD technique, an ALD technique, an electroplating technique, and/or another suitable deposition technique. The bonding pads 162 may be deposited in one or more deposition operations. In some implementations, a seed layer is first deposited, and the bonding pads 162 are deposited on the seed layer. In some implementations, one or more liners (e.g., a barrier liner, an adhesion liner) may first be deposited in the recess, and the bonding pads 162 may be deposited on the one or more liners in the recess. In some implementations, a planarization tool is used to perform a planarization operation (e.g., a CMP operation) to planarize the bonding pads 162 after the bonding pads 162 are deposited.

As indicated above, FIGS. 3A-3H are provided as an example. Other examples may differ from what is described with regard to FIGS. 3A-3H.

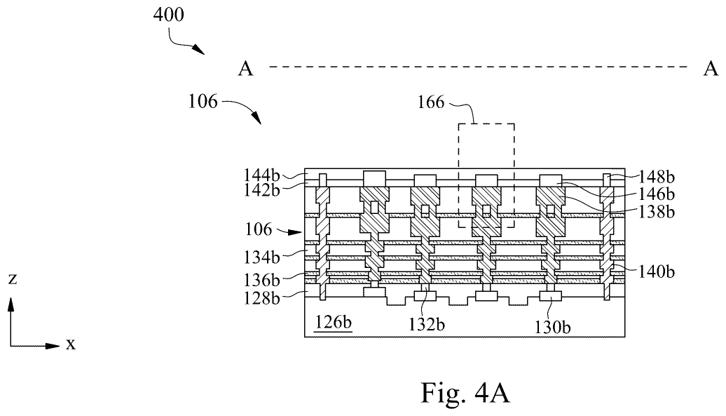

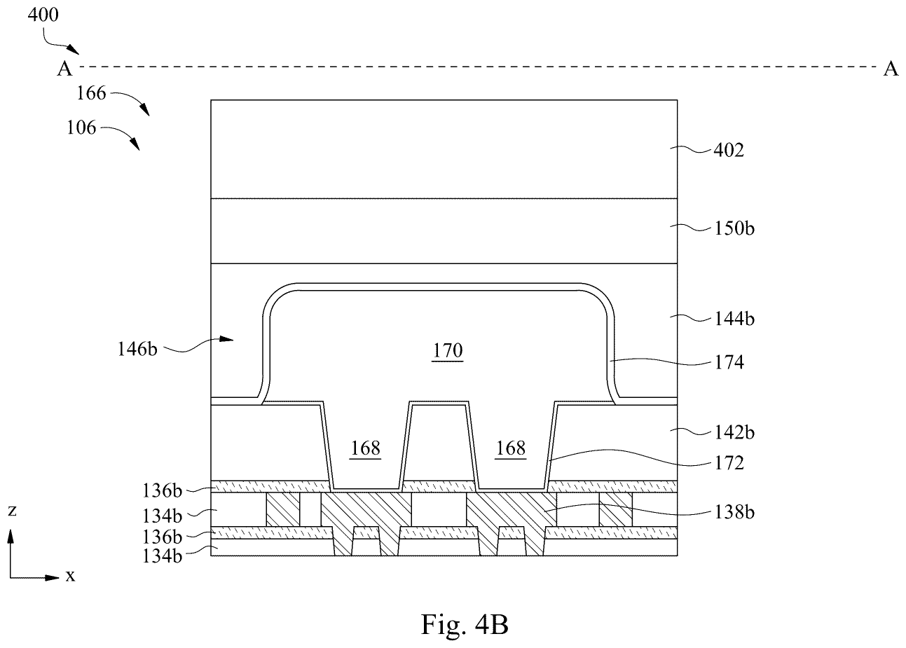

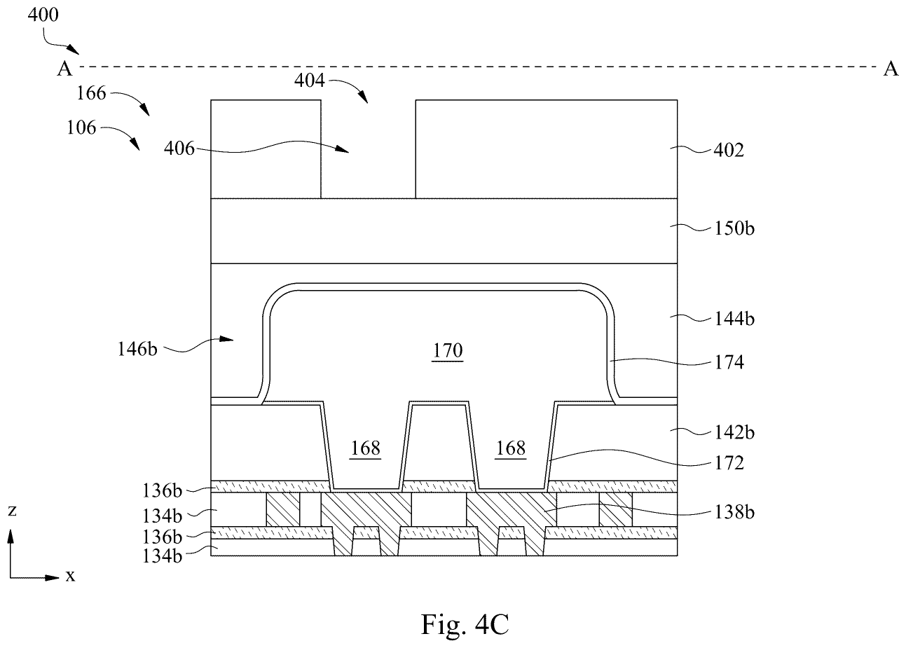

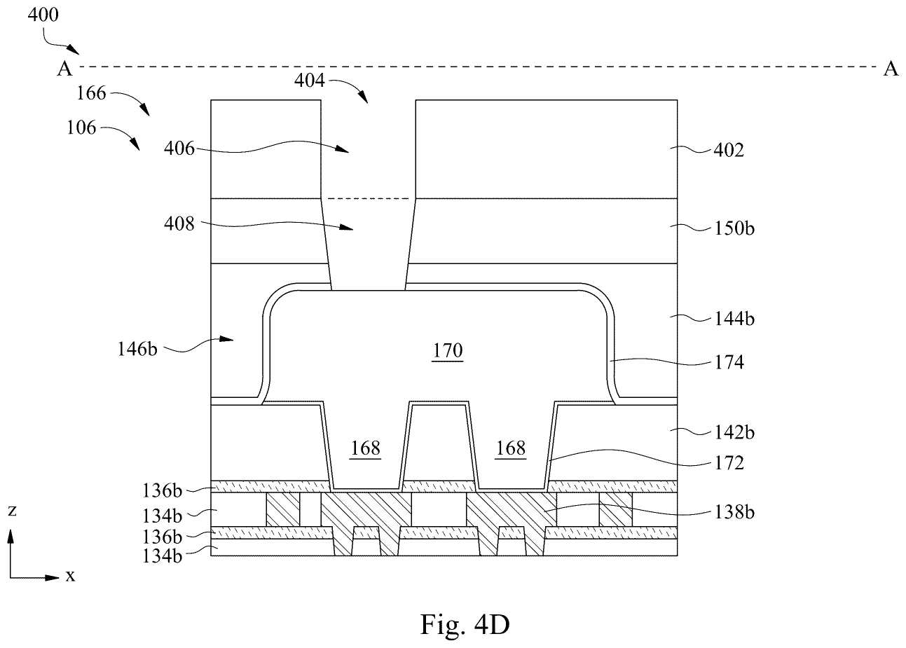

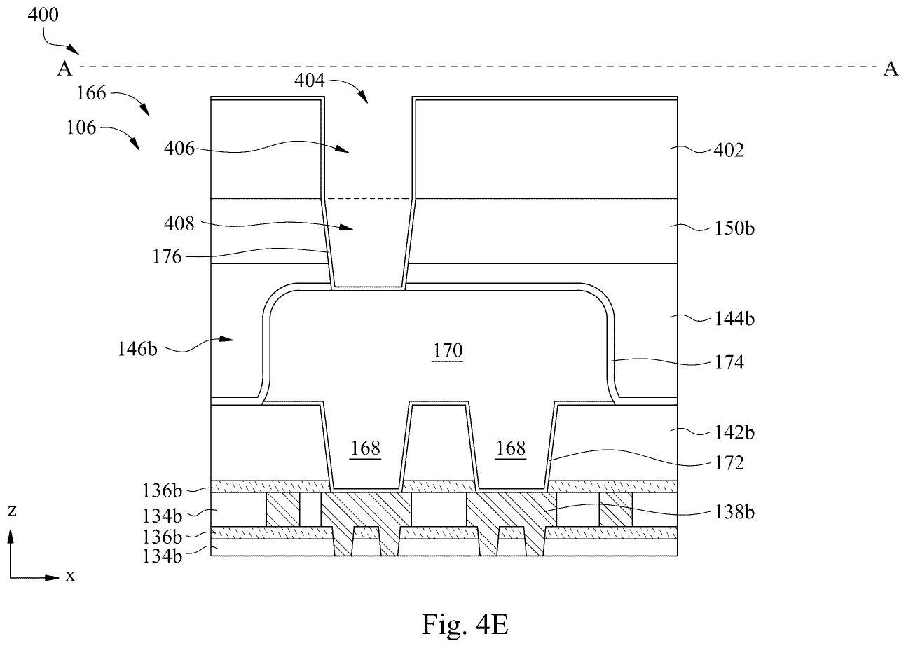

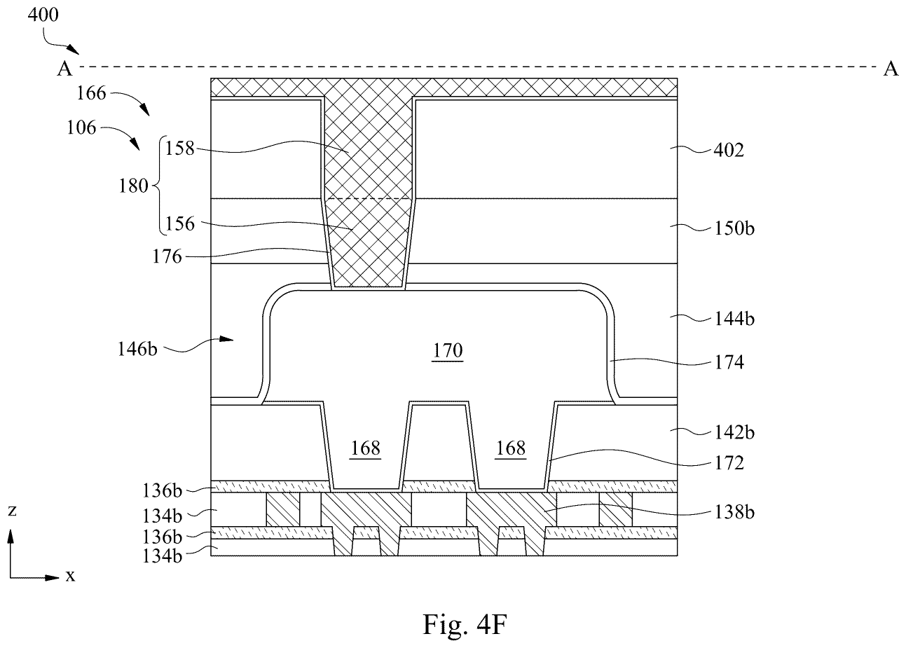

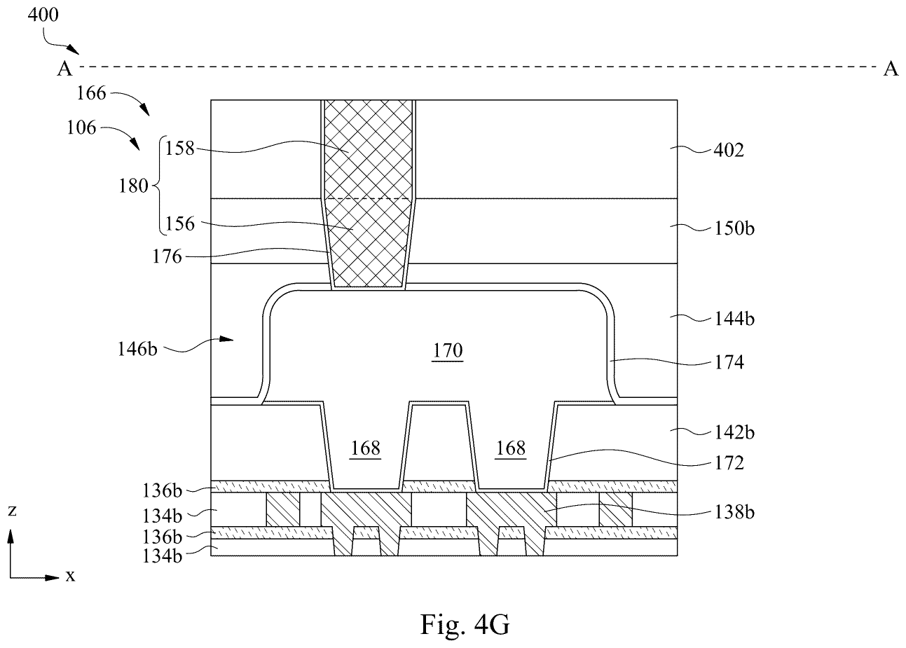

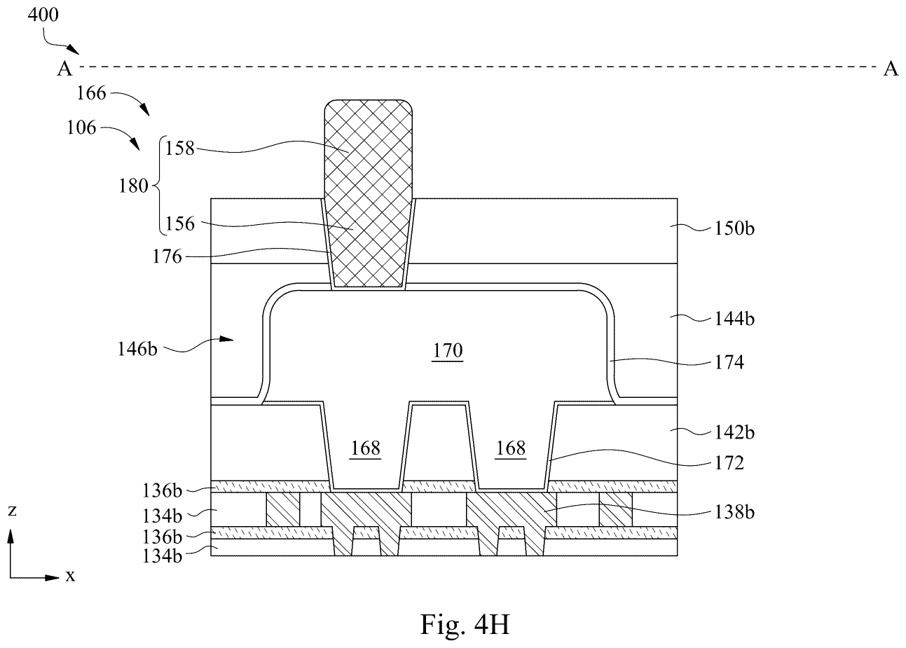

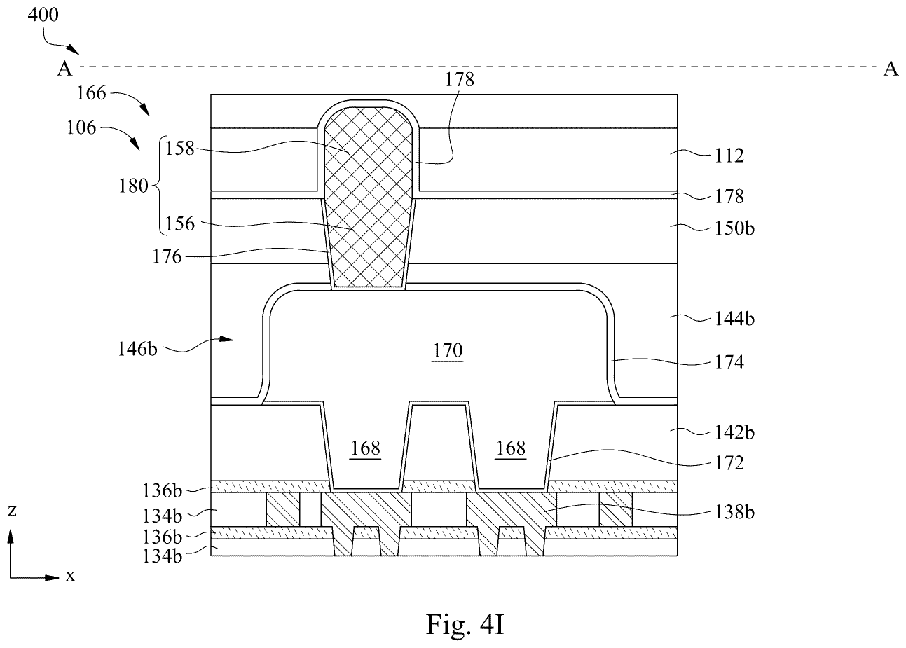

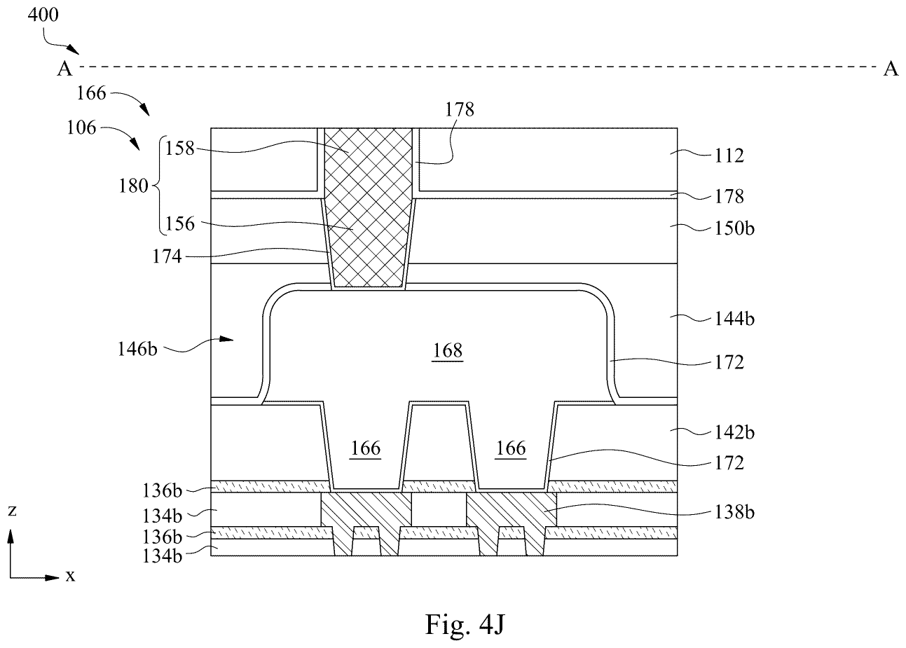

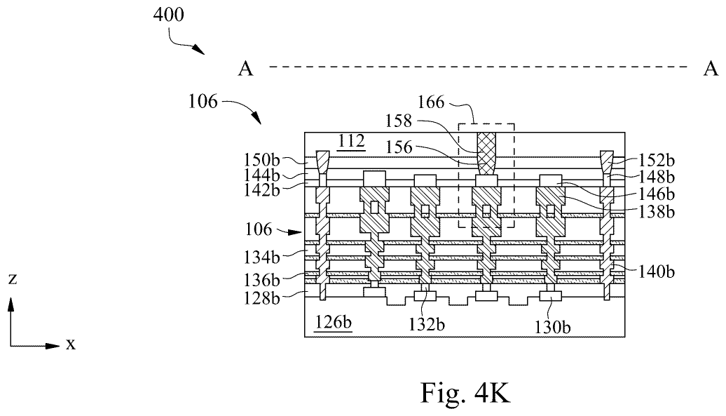

FIGS. 4A-4K are diagrams of an example implementation 400 of forming an IC die described herein. While the processing operations of the example implementation 400 are illustrated and described in connection with forming the IC die 106 described herein, the processing operations of the example implementation 400 may be performed to form another IC die described herein, such as the IC die 104. In some implementations, one or more of the semiconductor processing operations described in connection with FIGS. 4A-4K may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4A, similar processing operations as described in connection with FIGS. 3A-3E may be performed to form the IC devices 130b in and/or on the substrate 126b of the IC die 106, the ILD layer 128b, the contacts 132b, the ILD layers 134b, the ESLs 136b, the vertically-arranged layers of conductive structures 138b, the seal ring structure 140b, the passivation layers 142b and 144b, the metal pad structures 146b, and/or the metal pad structures 148b.

As shown in the close-up view of the portion 166 of the IC die 106 in FIG. 4B, the dielectric layer 150b may be formed over and/or on the passivation layer 144b such that the dielectric layer 150b is above a metal pad structure 146b of the IC die 106. As further shown in FIG. 4B, a photoresist layer 402 may be formed over and/or on the dielectric layer 150b. The photoresist layer 402 may be formed of one or more photoresist materials, such as organic photoresist materials and/or inorganic photoresist materials. The photoresist material of the photoresist layer 402 may be photosensitive, enabling the photoresist layer 402 to be patterned using photolithography techniques.

A deposition tool may be used to deposit the dielectric layer 150b using a PVD technique, an ALD technique, a CVD technique, an oxidation technique, and/or another suitable deposition technique. The dielectric layer 150b may be deposited in one or more deposition operations. In some implementations, a planarization tool may be used to perform a planarization operation (e.g., a CMP operation) to planarize the dielectric layer 150b after the dielectric layer 150b is deposited. A deposition tool may be used to deposit the photoresist layer 402 using a spin-coating technique and/or another suitable deposition technique.

As shown in the close-up view of the portion 166 of the IC die 106 in FIG. 4C, a recess 404 may be formed through the photoresist layer 402. The recess 404 may be formed over a portion of the metal pad structure 146b. The portion of the recess 404 formed through the photoresist layer 402 may correspond to a trench portion (or a top portion) 406 of the recess 404.

An exposure tool may be used to expose the photoresist layer to a radiation source to pattern the photoresist layer 402 to form the trench portion 406 of the recess 404. A developer tool may be used to develop and remove portions of the photoresist layer 402 to expose the pattern corresponding to the trench portion 406 of the recess 404. The trench portion 406 of the recess 404 may have substantially vertical sidewalls.

As shown in the close-up view of the portion 166 of the IC die 106 in FIG. 4D, a portion of the dielectric layer 150b exposed through the trench portion 406 of the recess 404 may be etched to extend the recess 404 through the dielectric layer 150b and to the underlying metal pad structure 146b. Thus, the recess 404 may extend through the photoresist layer 402, the dielectric layer 150b, and to the underlying metal pad structure 146b. In some implementations, the recess 404 may also extend through a portion of the passivation layer 144b above the metal pad structure 146b.

The portion of the recess 404 that extends through the dielectric layer 150b may correspond to a via portion 408 of the recess 404. The via portion 408 of the recess 404 may have tapered sidewalls such that a width of the recess 404 at the top of the via portion 408 is greater than a width of the recess 404 at the bottom of the via portion 408. Alternatively, the via portion 408 may have substantially vertical sidewalls.

An etch tool may be used to etch the dielectric layer 150b based on the pattern in the photoresist layer 402 (e.g., corresponding to the trench portion 406 of the recess 404) to form the via portion 408 of the recess in the dielectric layer 150b. In some implementations, the etch operation includes a dry etch operation (e.g., a plasma-based etch operation, a gas-based etch operation), a wet chemical etch operation, and/or another type of etch operation.

As shown in the close-up view of the portion 166 of the IC die 106 in FIG. 4E, a barrier liner 176 may be deposited on sidewalls of the recess 404 and on a bottom surface of the recess 404. For example, the barrier liner 176 may be deposited on the sidewalls of the trench portion 406 of the recess 404, on the sidewalls of the via portion 408 of the recess 404, and/or on the bottom surface of the via portion 408 of the recess 404. The barrier liner 176 may also extend along the top surface of the photoresist layer 402.

The barrier liner 176 may be conformally deposited in the recess. A deposition tool may be used to deposit the barrier liner 176 using a conformal deposition technique such as ALD and/or CVD, among other examples.

As shown in the close-up view of the portion 166 of the IC die 106 in FIG. 4F, a bonding structure 180 may be formed in the recess 404 such that the bonding structure 180 lands on the metal pad structure 146b. In particular, a bonding via 156 (or via portion or bottom portion of the bonding structure 180) may be formed in the via portion 408 of the recess 404 on the metal pad structure 146b, and a bonding pad 158 (or pad portion or top portion of the bonding structure 180) may be formed in the trench portion 406 of the recess 404 on the bonding via 156. The bonding via 156 may be formed on the barrier liner 176 such that the barrier liner 176 is between the bonding via 156 and the metal pad structure 146b, and between the bonding via 156 and the dielectric layer 150b. The bonding pad 158 may be formed such that the barrier liner 176 is between the bonding pad 158 and the photoresist layer 402.

A deposition tool may be used to deposit the bonding structure 180 (or the bonding via 156 and the bonding pad 158) using a deposition technique such as ALD, CVD, PVD, and/or electroplating, among other examples. As shown in FIG. 4F, excess material of the bonding structure 180 may be deposited over the top surface of the photoresist layer 402.

As shown in the close-up view of the portion 166 of the IC die 106 in FIG. 4G, a planarization operation may be performed to remove the excess material of the bonding structure 180 from the top of the photoresist layer 402. The portion of the barrier liner 176 on the top surface of the photoresist layer 402 may also be removed to reveal the photoresist layer 402 so that the photoresist layer 402 can be removed.

As shown in the close-up view of the portion 166 of the IC die 106 in FIG. 4H, the photoresist layer 402 may be removed from around the bonding pad 158. In some implementations, a photoresist removal tool is used to remove the photoresist layer 402 using a chemical stripping technique in which a chemical is used to strip or dissolve the photoresist layer 402. In some implementations, a photoresist removal tool is used to remove the photoresist layer 402 using a plasma ashing technique in which a plasma is used to decompose the photoresist layer 402. In some implementations, a photoresist removal tool is used to remove the photoresist layer 402 using another photoresist removal technique.

As further shown in FIG. 4H, the portion of the barrier liner 176 that was on the sidewalls of the bonding pad 158 is also removed. This exposes the sidewalls of the bonding pad 158. In some implementations, the portion of the barrier liner 176 on the sidewalls of the bonding pad 158 is removed during the process for removing the photoresist layer 402. In some implementations, a process is performed subsequent to removal of the photoresist layer 402 to remove the portion of the barrier liner 176 from the sidewalls of the bonding pad 158.

As shown in the close-up view of the portion 166 of the IC die 106 in FIG. 4I, the dielectric liner 178 is conformally deposited on the dielectric layer 150b and on the sidewalls and the top surface of the bonding pad 158. A deposition tool may be used to deposit the dielectric liner 178 using a conformal deposition technique such as ALD and/or CVD, among other examples.

As further shown in FIG. 4I, the bonding dielectric layer 112 is deposited around the bonding pad 158. The bonding dielectric layer 112 is deposited on the dielectric liner 178, and in some implementations is deposited over the bonding pad 158 such that the bonding pad 158 is covered by the bonding dielectric layer 112. A deposition tool may be used to deposit the bonding dielectric layer 112 using a PVD technique, an ALD technique, a CVD technique, an oxidation technique, and/or another suitable deposition technique.

As shown in the close-up view of the portion 166 of the IC die 106 in FIG. 4J, a planarization operation is performed to remove excess material from the bonding dielectric layer 112 to expose the top surface of the bonding pad 158 through the bonding dielectric layer 112. A planarization tool may be used to perform the planarization operation, and the planarization operation may include a CMP operation, a grinding operation, and/or another type of planarization operation. Additionally and/or alternatively, an etch operation may be performed to remove excess material from the bonding dielectric layer 112.

As shown in FIG. 4J, the planarization operation results in the top surface of the bonding dielectric layer 112 and the top surface of the bonding pad 158 being approximately co-planar. Removal of the barrier liner 176 from around the bonding pad 158 enables a substantially uniform surface across the bonding pad 158 and across the bonding dielectric layer 112 to be achieved with minimal to no voids.

As shown in FIG. 4K, in some implementations, bonding pads 152b on the seal ring structure 140b are also formed. In some implementations, the bonding pads 152b may be formed in a similar manner as illustrated in FIGS. 4B-4J for the bonding pads 158.

As indicated above, FIGS. 4A-4K are provided as an example. Other examples may differ from what is described with regard to FIGS. 4A-4K.

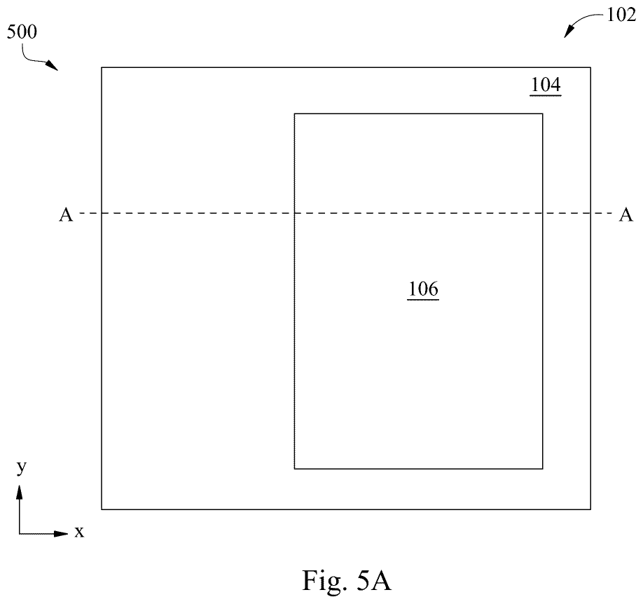

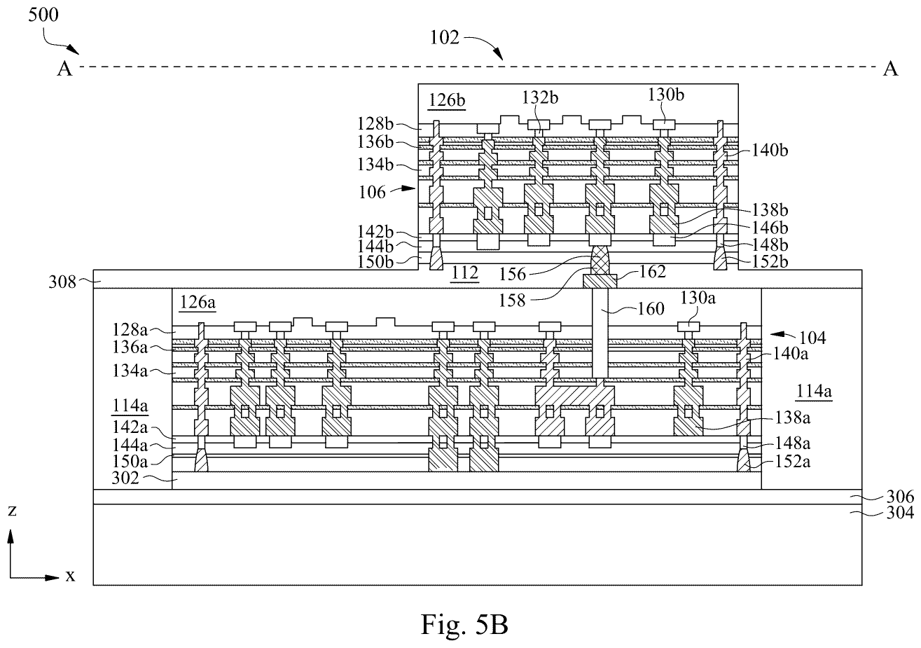

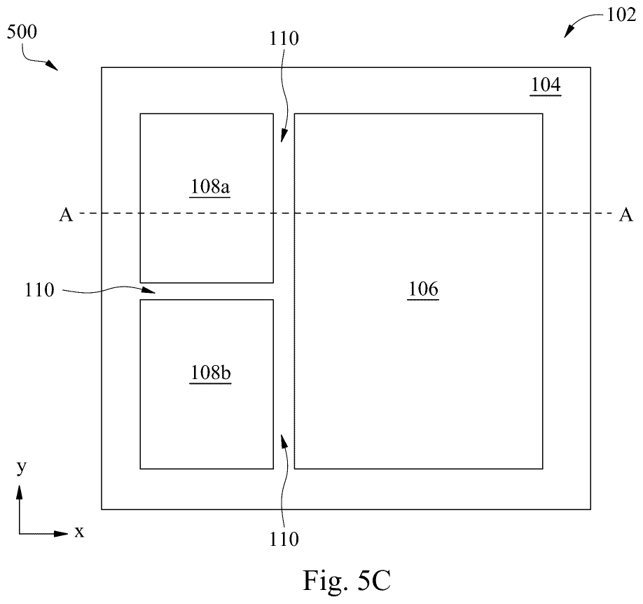

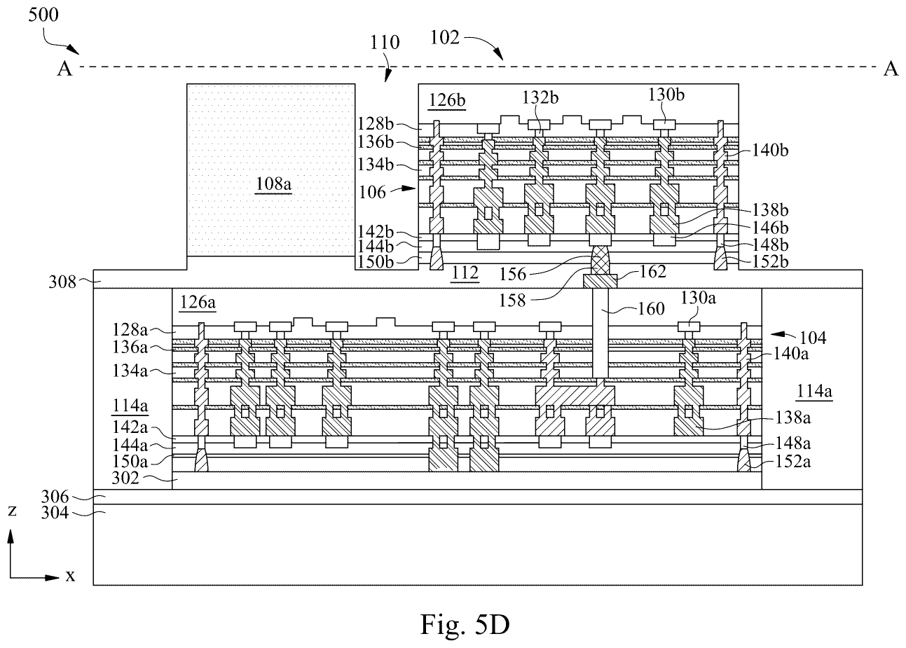

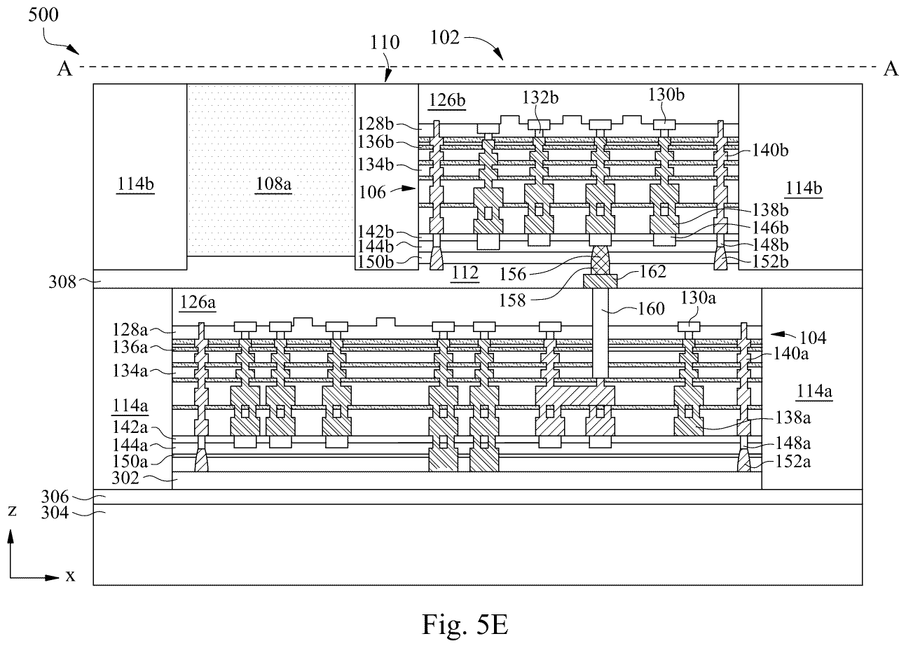

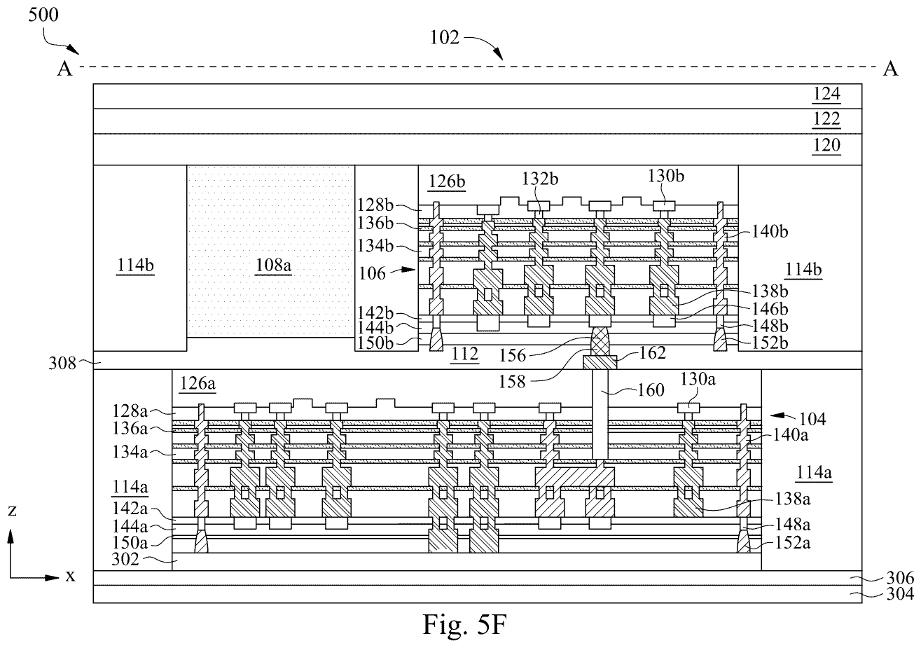

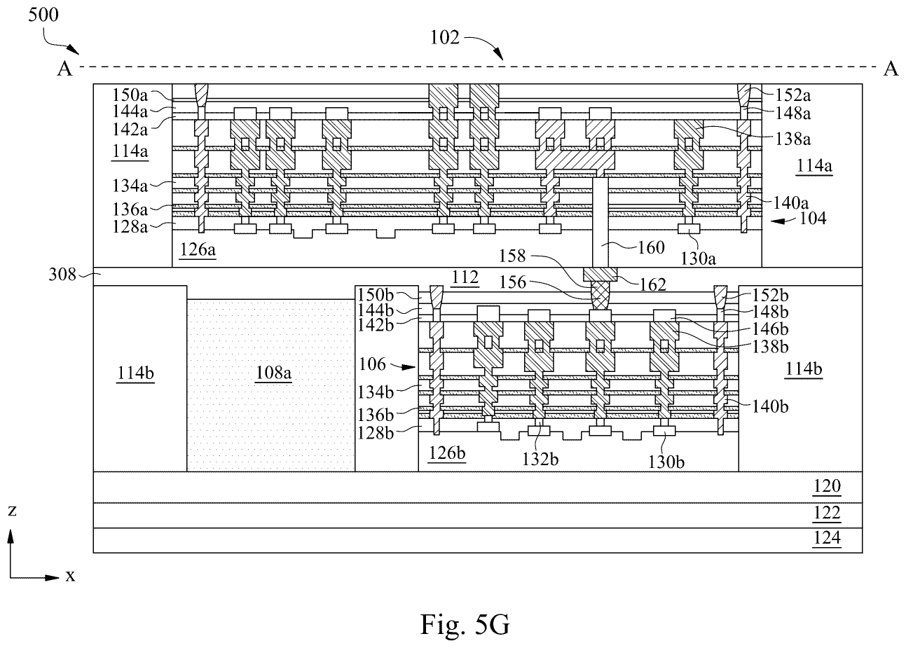

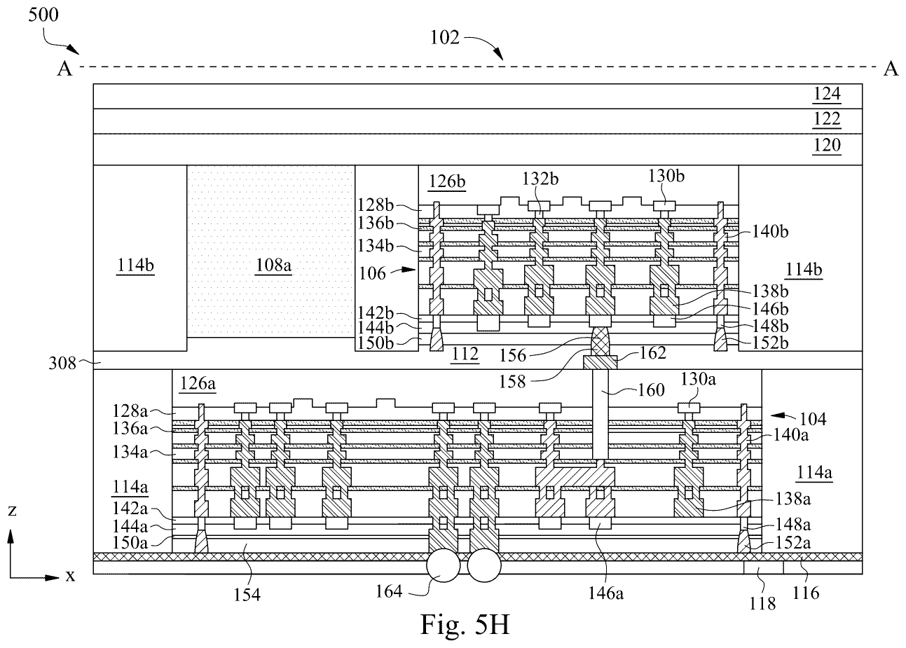

FIGS. 5A-5H are diagrams of an example implementation 500 of forming a semiconductor die package 102 described herein. In some implementations, one or more of the semiconductor processing operations described in connection with FIGS. 5A-5H may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIGS. 5A and 5B, the IC die 106 is bonded to the IC die 104 such that the IC die 104 and the IC die 106 are stacked and vertically arranged in the semiconductor die package 102. In some implementations, a bonding tool is used to bond the IC die 104 and the IC die 106 by forming dielectric-to-dielectric bonds between bonding dielectric layer 112 on the IC die 106 and the bonding dielectric layer 308 on the IC die 104. In some implementations, a bonding tool is used to bond the IC die 104 and the IC die 106 by forming metal-to-metal bonds between the bonding pad 162 on the back side of the IC die 104 and the bonding pad 158 of the IC die 106. In some implementations, a bonding tool is used to bond the IC die 104 and the IC die 106 by forming a combination of dielectric-to-dielectric bonds and metal-to-metal bonds. In some implementations, a bonding tool is used to bond the IC die 104 and the IC die 106 by forming a dielectric-to-metal bond between the bonding pad 158 of the IC die 106 and the bonding dielectric layer 308 of the IC die 104.

As shown in FIGS. 5C and 5D, the non-active dies 108a and 108b may be provided over and/or on the IC die 104 such that the non-active dies 108a and 108b are laterally adjacent to one or more sides of the IC die 106. In particular, the non-active dies 108a and 108b may be provided over and/or on the same side of the IC die 104 to which the IC die 106 is bonded. In some implementations, the non-active dies 108a and/or 108b include semiconductor dies (e.g., silicon dies), and the non-active dies 108a and/or 108b are bonded to the bonding dielectric layer 308. In some implementations, the non-active dies 108a and/or 108b include dielectric layers (e.g., dielectric thick films) that are deposited onto the IC die 104 using a deposition tool. In these implementations, the non-active dies 108a and/or 108b may be deposited using a CVD technique, a PVD technique, an ALD technique, an oxidation technique, and/or another suitable deposition technique.

As shown in FIG. 5E, areas around the IC die 106, areas around the non-active die 108a, and areas around the non-active die 108b are filled with the dielectric fill layer 114b. If the IC die 106, the non-active die 108a, and/or the non-active die 108b are spaced apart by gaps 110, the gaps 110 may be filled in with material of the dielectric fill layer 114b. A deposition tool may be used to deposit the dielectric fill layer 114b using a PVD technique, an ALD technique, a CVD technique, an oxidation technique, and/or another suitable deposition technique. The dielectric fill layer 114b may be deposited in one or more deposition operations. A planarization tool may be used to perform a planarization operation (e.g., a CMP operation) to planarize the dielectric fill layer 114b, the substrate 126b of the IC die 106, and the non-active dies 108a and 108b such that the dielectric fill layer 114b, the substrate 126b of the IC die 106, and the non-active dies 108a and 108b are approximately co-planar.

As shown in FIG. 5F, the passivation layers 120-124 are formed or provided above the IC die 106. A deposition tool may be used to deposit the passivation layers 120-124 using a PVD technique, an ALD technique, a CVD technique, an oxidation technique, and/or another suitable deposition technique. The passivation layers 120-124 may be deposited in one or more deposition operations.

In some implementations, a planarization tool may be used to perform a planarization operation (e.g., a CMP operation) to planarize the passivation layers 120-124 after the passivation layers 120-124 are deposited. Additionally and/or alternatively, one or more of the passivation layers 120-124 may be dispensed onto the IC die 104. Additionally and/or alternatively, the semiconductor die package 102 may be placed over and/or on one or more of the passivation layers 120-124 on a carrier substrate.

As shown in FIG. 5G, the semiconductor die package 102 is flipped and one or more operations are performed to remove the carrier substrate 304 and the bonding layers 302 and 306 from the semiconductor die package 102. In some implementations, the carrier substrate 304 is de-bonded from the semiconductor die package 102 by a thermal operation to alter the adhesive properties of the bonding layers 302 and/or 306. An energy source such as an ultraviolet (UV) laser, a carbon dioxide (CO₂) laser, or an infrared (IR) laser, among other examples, is utilized to irradiate and heat the bonding layers 302 and/or 306 until the adhesive properties of the bonding layer 302 and/or 306 are reduced. Then, the carrier substrate 304 and the bonding layers 302 and 306 are physically separated and removed from the semiconductor die package 102. Additionally and/or alternatively, the carrier substrate 304, the bonding layer 302, and/or the bonding layer 306 may be removed by etching and/or planarization.

As shown in FIG. 5H, the passivation layers 116 and 118 are formed on the IC die 104. A deposition tool may be used to deposit the passivation layers 116 and 118 using a PVD technique, an ALD technique, a CVD technique, an oxidation technique, and/or another suitable deposition technique. The passivation layers 116 and 118 may be deposited in one or more deposition operations. In some implementations, a planarization tool may be used to perform a planarization operation (e.g., a CMP operation) to planarize the passivation layers 116 and 118 after the passivation layers 116 and 118 are deposited. Additionally and/or alternatively, passivation layers 116 and/or 118 may be dispensed onto the IC die 104. The connection structures 164 may also be attached to the semiconductor die package 102.

As indicated above, FIGS. 5A-5H are provided as an example. Other examples may differ from what is described with regard to FIGS. 5A-5H.

FIGS. 6-9 illustrate example implementations of bonding arrangements for bonding a bonding pad 158 of the IC die 106 to the IC die 104 in the semiconductor die package 102 described herein. While FIGS. 6-9 provide various example implementations of bonding arrangements, other example implementations of bonding arrangements are within the scope of the present disclosure. Moreover, the semiconductor die package 102 may include a plurality of bonding arrangements.

As shown in FIG. 6, an example implementation 600 of a bonding arrangement includes a bonding pad 158 (or a pad portion of a bonding structure 180) of the IC die 106 bonded to a bonding pad 162 of the IC die 104 in a metal-to-metal bond. The metal-to-metal bond between the bonding pad 158 and the bonding pad 162 provides an electrical connection between the IC die 104 and the IC die 106.

The bonding pad 162 is included in the bonding dielectric layer 308. The bonding dielectric layer 308 of the IC die 104 and the bonding dielectric layer 112 of the IC die 106 are bonded together in a dielectric-to-dielectric bond.

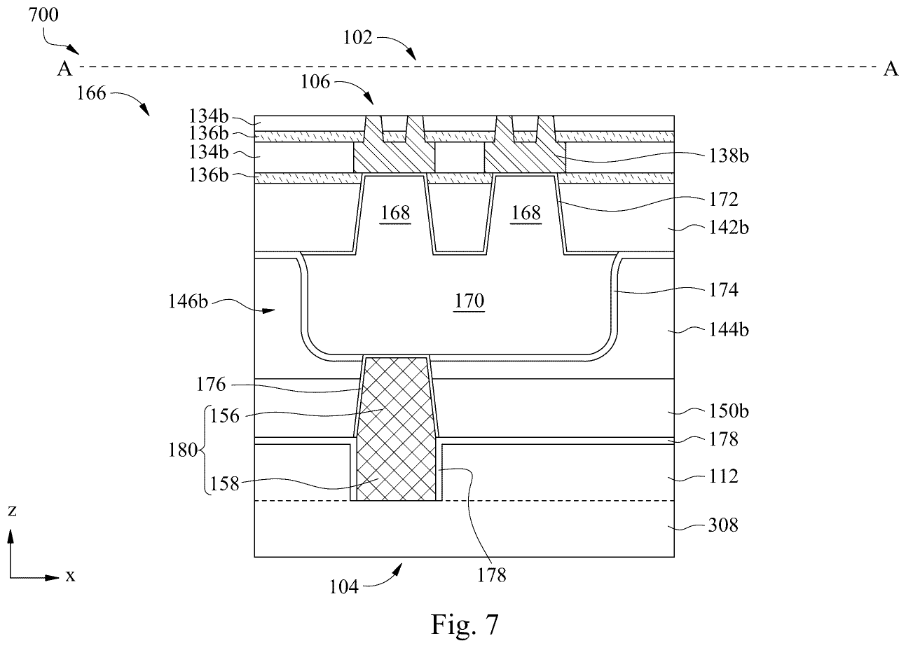

As shown in FIG. 7, an example implementation 700 of a bonding arrangement includes a bonding pad 158 (or a pad portion of a bonding structure 180) of the IC die 106 bonded to the bonding dielectric layer 308 of the IC die 104 in a metal-to-dielectric bond. In the example implementation 700, the bonding pad 158 is used as a dummy structure (e.g., is not used to provide an electrical connection between the IC die 104 and the IC die 106) and is included to achieve a particular pattern density in the IC die 106.

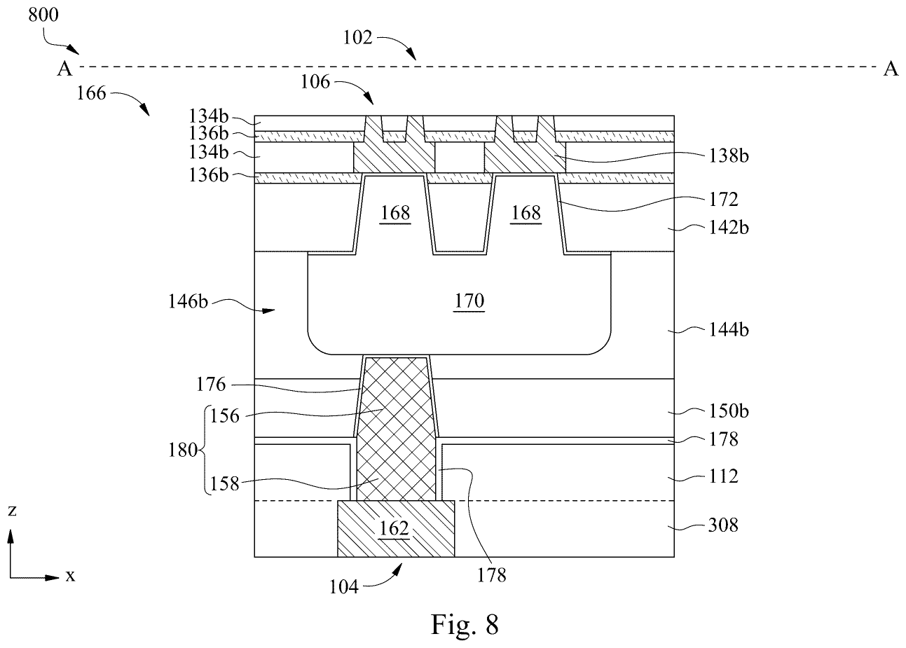

As shown in FIG. 8, an example implementation 800 of a bonding arrangement includes a bonding pad 158 (or a pad portion of a bonding structure 180) of the IC die 106 bonded to a bonding pad 162 of the IC die 104 in a metal-to-metal bond. The metal-to-metal bond between the bonding pad 158 and the bonding pad 162 provides an electrical connection between the IC die 104 and the IC die 106.

As further shown in FIG. 8, a bonding via 156 (or a via portion of the bonding structure 180) of the IC die 106 is coupled to a metal pad structure 146b of the IC die 106. The metal pad structure 146b in the example implementation 800 is formed of aluminum (Al), unlike the metal pad structures 146b illustrated in the example implementations 600 and 700 (which may be formed of another metal such as copper (Cu)). Accordingly, the dielectric liner 174 may be omitted from around the trench portion 170 of the metal pad structure 146b in the example implementation 800.

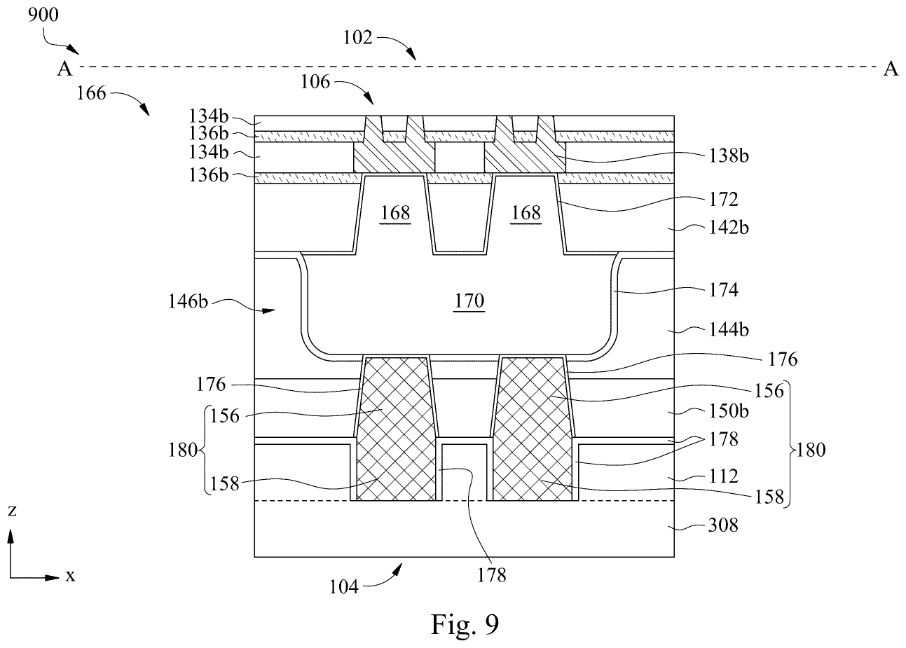

As shown in FIG. 9, an example implementation 900 of a bonding arrangement includes a plurality of bonding pads 158 (or pad portions of a plurality of bonding structures 180) of the IC die 106 bonded to the IC die 104. In the example implementation 900, a plurality of bonding vias 156 (or via portions of the plurality of bonding structures 180) are coupled to the same metal pad structure 146b. The plurality of bonding pads 158 (or pad portions of the plurality of bonding structures 180) may be bonded to the bonding dielectric layer 308 of the IC die 104 in metal-to-dielectric bonds, and/or may be bonded to bonding pads 162 of the IC die 104 in metal-to-metal bonds.

As indicated above, FIGS. 6-9 are provided as examples. Other examples may differ from what is described with regard to FIGS. 6-9.

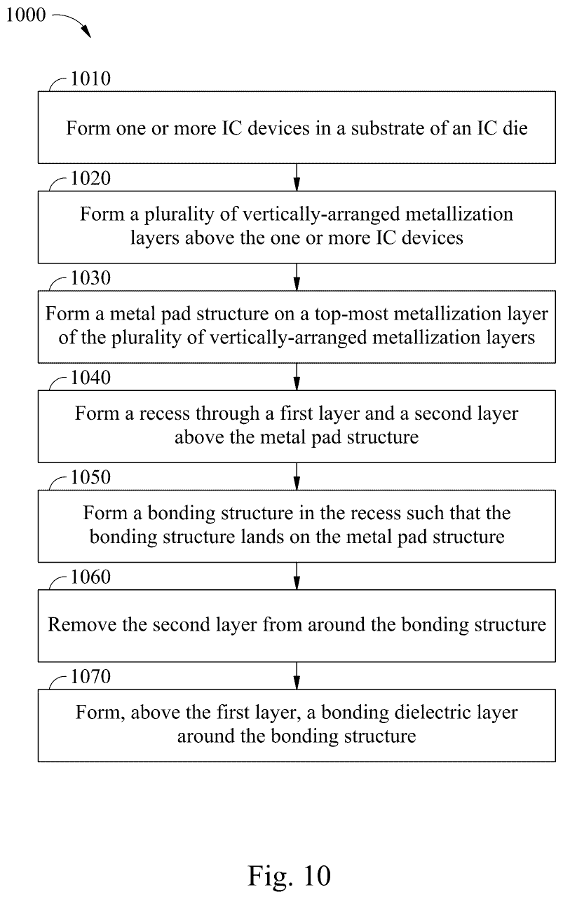

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming one or more IC devices in a substrate of an IC die (block 1010). For example, one or more semiconductor processing tools may be used to form one or more IC devices (e.g., IC devices 130b) in a substrate (e.g., a substrate 126b) of an IC die (e.g., an IC die 106), as described herein.

As further shown in FIG. 10, process 1000 may include forming a plurality of vertically-arranged metallization layers above the one or more IC devices (block 1020). For example, one or more semiconductor processing tools may be used to form a plurality of vertically-arranged metallization layers (e.g., vertically-arranged conductive structures 138b) above the one or more IC devices, as described herein.

As further shown in FIG. 10, process 1000 may include forming a metal pad structure on a top-most metallization layer of the plurality of vertically-arranged metallization layers (block 1030). For example, one or more semiconductor processing tools may be used to form a metal pad structure (e.g., a metal pad structure 146b) on a top-most metallization layer of the plurality of vertically-arranged metallization layers, as described herein.

As further shown in FIG. 10, process 1000 may include forming a recess (404) through a first layer and a second layer above the metal pad structure (block 1040). For example, one or more semiconductor processing tools may be used to form a recess (e.g., a recess 404) through a first layer (e.g., a dielectric layer 150b) and a second layer (e.g., a photoresist layer 402) above the metal pad structure, as described herein.

As further shown in FIG. 10, process 1000 may include forming a bonding structure in the recess such that the bonding structure lands on the metal pad structure (block 1050). For example, one or more semiconductor processing tools may be used to form a bonding structure (e.g., a bonding structure 180, a bonding via 156 and a bonding pad 158) in the recess such that the bonding structure lands on the metal pad structure, as described herein.

As further shown in FIG. 10, process 1000 may include removing the second layer from around the bonding structure (block 1060). For example, one or more semiconductor processing tools may be used to remove the second layer from around the bonding structure, as described herein.

As further shown in FIG. 10, process 1000 may include forming, above the first layer, a bonding dielectric layer around the bonding structure (block 1070). For example, one or more semiconductor processing tools may be used to form, above the first layer, a bonding dielectric layer (e.g., a bonding dielectric layer 112) around the bonding structure, as described herein.

Process 1000 may include additional implementations, such as any single implementation or any combination of implementations described below and/or in connection with one or more other processes described elsewhere herein.

In a first implementation, the first layer includes a dielectric layer and the second layer includes a photoresist layer.

In a second implementation, alone or in combination with the first implementation, forming the bonding structure comprises forming a via portion (e.g., a bonding via 156) of the bonding structure in a first portion (e.g., a via portion 408) of the recess through the first layer, and forming a pad portion (e.g., a bonding pad 158) of the bonding structure in a second portion (e.g., a trench portion 406) of the recess through the second layer.

In a third implementation, alone or in combination with one or more of the first and second implementations, the second layer is above the first layer and the pad portion is above the via portion.

In a fourth implementation, alone or in combination with one or more of the first through third implementations, forming the bonding structure includes forming a barrier liner (e.g., a barrier liner 176) on sidewalls of the first portion of the recess and on sidewalls of the second portion of the recess, forming the via portion of the bonding structure such that the barrier liner is between sidewalls of the via portion and the sidewalls of the first portion of the recess, and forming the pad portion of the bonding structure such that the barrier liner is between sidewalls of the pad portion and the sidewalls of the second portion of the recess.

In a fifth implementation, alone or in combination with one or more of the first through fourth implementations, process 1000 includes removing the barrier liner from the sidewalls of the pad portion of the bonding structure.

In a sixth implementation, alone or in combination with one or more of the first through fifth implementations, process 1000 includes forming a dielectric liner (e.g., a dielectric liner 178) directly on sidewalls of the bonding structure after removing the second layer from around the bonding structure, where the dielectric liner has a dielectric constant that is less than a dielectric constant of tantalum nitride (TaN).

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

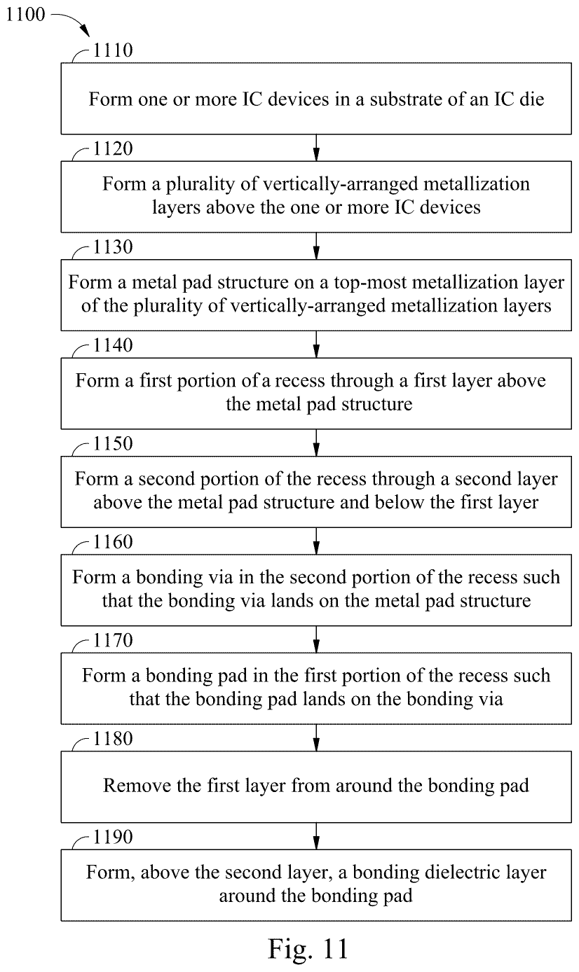

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming one or more IC devices in a substrate of an IC die (block 1110). For example, one or more semiconductor processing tools may be used to form one or more IC devices (e.g., IC devices 130b) in a substrate (e.g., a substrate 126b) of an IC die (e.g., an IC die 106), as described herein.

As further shown in FIG. 11, process 1100 may include forming a plurality of vertically-arranged metallization layers above the one or more IC devices (block 1120). For example, one or more semiconductor processing tools may be used to form a plurality of vertically-arranged metallization layers (e.g., vertically-arranged conductive structures 138b) above the one or more IC devices, as described herein.

As further shown in FIG. 11, process 1100 may include forming a metal pad structure on a top-most metallization layer of the plurality of vertically-arranged metallization layers (block 1130). For example, one or more semiconductor processing tools may be used to form a metal pad structure (e.g., a metal pad structure 146b) on a top-most metallization layer of the plurality of vertically-arranged metallization layers, as described herein.

As further shown in FIG. 11, process 1100 may include forming a first portion of a recess through a first layer above the metal pad structure (block 1140). For example, one or more semiconductor processing tools may be used to form a first portion (e.g., a trench portion 406) of a recess (e.g., a recess 404) through a first layer (e.g., a photoresist layer 402) above the metal pad structure, as described herein.

As further shown in FIG. 11, process 1100 may include forming a second portion of the recess through a second layer above the metal pad structure and below the first layer (block 1150). For example, one or more semiconductor processing tools may be used to form a second portion (e.g., a via portion 408) of the recess through a second layer (e.g., a dielectric layer 150b) above the metal pad structure and below the first layer, as described herein.

As further shown in FIG. 11, process 1100 may include forming a bonding via in the second portion of the recess such that the bonding via lands on the metal pad structure (block 1160). For example, one or more semiconductor processing tools may be used to form a bonding via (e.g., a bonding via 156) in the second portion of the recess such that the bonding via lands on the metal pad structure, as described herein.

As further shown in FIG. 11, process 1100 may include forming a bonding pad in the first portion of the recess such that the bonding pad lands on the bonding via (block 1170). For example, one or more semiconductor processing tools may be used to form a bonding pad (e.g., a bonding pad 158) in the first portion of the recess such that the bonding pad lands on the bonding via, as described herein.

As further shown in FIG. 11, process 1100 may include removing the first layer from around the bonding pad (block 1180). For example, one or more semiconductor processing tools may be used to remove the first layer from around the bonding pad, as described herein.

As further shown in FIG. 11, process 1100 may include forming, above the second layer, a bonding dielectric layer around the bonding pad (block 1190). For example, one or more semiconductor processing tools may be used to form, above the second layer, a bonding dielectric layer (e.g., a bonding dielectric layer 112) around the bonding pad, as described herein.

Process 1100 may include additional implementations, such as any single implementation or any combination of implementations described below and/or in connection with one or more other processes described elsewhere herein.

In a first implementation, process 1100 includes forming a tantalum-based barrier liner (e.g., a barrier liner 176) on sidewalls of the recess, where forming the bonding via includes forming the bonding via on the tantalum-based barrier liner, and where forming the bonding pad includes forming the bonding pad such that the tantalum-based barrier liner is between the sidewalls of the bonding pad and the first layer.

In a second implementation, alone or in combination with the first implementation, process 1100 includes removing the tantalum-based barrier liner from the sidewalls of the bonding pad, and forming a silicon-based dielectric liner (e.g., a dielectric liner 178) on the sidewalls of the bonding pad.

In a third implementation, alone or in combination with one or more of the first and second implementations, forming the bonding dielectric layer includes forming the bonding dielectric layer such that the silicon-based dielectric liner is between the sidewalls of the bonding pad and the bonding dielectric layer.

In a fourth implementation, alone or in combination with one or more of the first through third implementations, removing the first layer from around the bonding pad includes performing a chemical stripping operation to remove the first layer, or performing a plasma ashing operation to remove the first layer.

In a fifth implementation, alone or in combination with one or more of the first through fourth implementations, forming the first portion of the recess includes forming the first portion of the recess by photolithography patterning, and forming the second portion of the recess comprises forming the second portion of the recess by etching.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a first IC die and a second IC die are bonded together in a stacked arrangement in a device package. The second IC die includes at least one bonding structure that is bonded to the first IC die. The bonding structure is formed in a manner such that a barrier layer is omitted from the sidewalls of a top portion of the bonding structure. The barrier layer is removed and replaced with a dielectric liner that is formed on the sidewalls after the bonding structure is formed. The dielectric liner has a material removal rate (e.g., for processes such as CMP, grinding, and/or chemical-based surface cleaning) that is closer to the material removal rate of the bonding structure than the material removal rate of the barrier liner. This reduces the likelihood of the formation of voids in the bond between the first IC die and the second IC die that might otherwise occur due to excessive material removal from the bonding structure. In this way, the removal of the barrier liner from around the top portion of the bonding structure enables strong electrical connections to be formed between the bonding structure and the first IC die, which may increase the electrical performance of the device package in that electrical resistance and/or power consumption of the device package may be reduced. Additionally and/or alternatively, the removal of the barrier liner from around the top portion of the bonding structure enables increased mechanical strength to be achieved for the bonds between the bonding structure and the first IC die, which may reduce the likelihood of delamination between the first IC die and the second IC die.

As described in greater detail above, some implementations described herein provide a method. The method includes forming one or more IC devices in a substrate of an IC die. The method includes forming a plurality of vertically-arranged metallization layers above the one or more IC devices. The method includes forming a metal pad structure on a top-most metallization layer of the plurality of vertically-arranged metallization layers. The method includes forming a recess through a first layer and a second layer above the metal pad structure. The method includes forming a bonding structure in the recess such that the bonding structure lands on the metal pad structure. The method includes removing the second layer from around the bonding structure. The method includes forming, above the first layer, a bonding dielectric layer around the bonding structure.

As described in greater detail above, some implementations described herein provide a method. The method includes forming one or more IC devices in a substrate of an IC die. The method includes forming a plurality of vertically-arranged metallization layers above the one or more IC devices. The method includes forming a metal pad structure on a top-most metallization layer of the plurality of vertically-arranged metallization layers. The method includes forming a first portion of a recess through a first layer above the metal pad structure. The method includes forming a second portion of the recess through a second layer above the metal pad structure and below the first layer. The method includes forming a bonding via in the second portion of the recess such that the bonding via lands on the metal pad structure. The method includes forming a bonding pad in the first portion of the recess such that the bonding pad lands on the bonding via. The method includes removing the first layer from around the bonding pad. The method includes forming, above the second layer, a bonding dielectric layer around the bonding pad.

As described in greater detail above, some implementations described herein provide a device package. The device package includes a first IC die. The device package includes a second IC die bonded to and vertically arranged with the first IC die. The first IC die includes a bonding via coupled to a metal pad structure that is vertically adjacent to the bonding via. The first IC die includes a barrier liner on sidewalls of the bonding via. The first IC die includes a bonding pad coupled to the bonding via. The bonding pad is vertically adjacent to the bonding via. The bonding via is vertically between the bonding pad and the metal pad structure. The first IC die includes a dielectric layer on sidewalls of the bonding pad. The barrier liner and the dielectric layer comprise different materials.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more integrated circuit (IC) devices in a substrate of an IC die;
forming a plurality of vertically-arranged metallization layers above the one or more IC devices;
forming a metal pad structure on a top-most metallization layer of the plurality of vertically-arranged metallization layers;
forming a recess through a first layer and a second layer above the metal pad structure;
forming a bonding structure in the recess such that the bonding structure lands on the metal pad structure;
removing the second layer from around the bonding structure; and
forming, above the first layer, a bonding dielectric layer around the bonding structure.

2. The method of claim 1, wherein the first layer comprises a dielectric layer; and
wherein the second layer comprises a photoresist layer.

3. The method of claim 1, wherein forming the bonding structure comprises:
forming a via portion of the bonding structure in a first portion of the recess through the first layer; and
forming a pad portion of the bonding structure in a second portion of the recess through the second layer.

4. The method of claim 3, wherein the second layer is above the first layer; and
wherein the pad portion is above the via portion.

5. The method of claim 3, wherein forming the bonding structure comprises:
forming a barrier liner on sidewalls of the first portion of the recess and on sidewalls of the second portion of the recess;
forming the via portion of the bonding structure such that the barrier liner is between sidewalls of the via portion and the sidewalls of the first portion of the recess; and
forming the pad portion of the bonding structure such that the barrier liner is between sidewalls of the pad portion and the sidewalls of the second portion of the recess.

6. The method of claim 5, further comprising:
removing the barrier liner from the sidewalls of the pad portion of the bonding structure.

7. The method of claim 1, further comprising:
forming a dielectric liner directly on sidewalls of the bonding structure after removing the second layer from around the bonding structure,
wherein the dielectric liner has a dielectric constant that is less than a dielectric constant of tantalum nitride (TaN).

8. A method, comprising:
forming one or more integrated circuit (IC) devices in a substrate of an IC die;
forming a plurality of vertically-arranged metallization layers above the one or more IC devices;
forming a metal pad structure on a top-most metallization layer of the plurality of vertically-arranged metallization layers;
forming a first portion of a recess through a first layer above the metal pad structure;
forming a second portion of the recess through a second layer above the metal pad structure and below the first layer;
forming a bonding via in the second portion of the recess such that the bonding via lands on the metal pad structure;
forming a bonding pad in the first portion of the recess such that the bonding pad lands on the bonding via;
removing the first layer from around the bonding pad; and
forming, above the second layer, a bonding dielectric layer around the bonding pad.

9. The method of claim 8, further comprising:
forming a tantalum-based barrier liner on sidewalls of the recess,
wherein forming the bonding via comprises forming the bonding via on the tantalum-based barrier liner, and
wherein forming the bonding pad comprises forming the bonding pad such that the tantalum-based barrier liner is between the sidewalls of the bonding pad and the first layer.

10. The method of claim 9, further comprising:
removing the tantalum-based barrier liner from the sidewalls of the bonding pad; and
forming a silicon-based dielectric liner on the sidewalls of the bonding pad.

11. The method of claim 10, wherein forming the bonding dielectric layer comprises:
forming the bonding dielectric layer such that the silicon-based dielectric liner is between the sidewalls of the bonding pad and the bonding dielectric layer.

12. The method of claim 8, wherein removing the first layer from around the bonding pad comprises:
performing a chemical stripping operation to remove the first layer, or
performing a plasma ashing operation to remove the first layer.

13. The method of claim 8, wherein forming the first portion of the recess comprises:
forming the first portion of the recess by photolithography patterning; and
wherein forming the second portion of the recess comprises:
forming the second portion of the recess by etching.

14. A device package, comprising:
a first integrated circuit (IC) die; and
a second IC die bonded to and vertically arranged with the first IC die,
wherein the first IC die comprises:
a bonding via coupled to a metal pad structure that is vertically adjacent to the bonding via;
a barrier liner on sidewalls of the bonding via;
a bonding pad coupled to the bonding via,
wherein the bonding pad is vertically adjacent to the bonding via, and
wherein the bonding via is vertically between the bonding pad and the metal pad structure; and
a dielectric layer on sidewalls of the bonding pad,
wherein the barrier liner and the dielectric layer comprise different materials.

15. The device package of claim 14, wherein the barrier liner comprises at least one of:
tantalum (Ta), or
tantalum nitride (TaN); and
wherein the dielectric layer comprises at least one of:
a silicon oxide (SiOₓ),
a silicon nitride (SiₓN_{y}),
a silicon oxynitride (SiON),
a silicon oxycarbide (SiOC), or
a silicon carbonitride (SiCN).

16. The device package of claim 14, wherein the bonding pad is bonded to a through-substrate interconnect structure included in the second IC die.

17. The device package of claim 14, wherein the bonding pad is bonded to a bonding dielectric layer included in the second IC die.

18. The device package of claim 14, wherein the first IC die further comprises:
another bonding via coupled to the metal pad structure that is vertically adjacent to the other bonding via;
another barrier liner on sidewalls of the other bonding via; and
another bonding pad coupled to the other bonding via,
wherein the other bonding pad is vertically adjacent to the other bonding via,
wherein the other bonding via is vertically between the other bonding pad and the metal pad structure, and
wherein the dielectric layer is on sidewalls of the other bonding pad.

19. The device package of claim 14, wherein the metal pad structure comprises a first metal material;
wherein the bonding via and the bonding pad comprise a second metal material; and
wherein the first metal material and the second metal material are different metal materials.

20. The device package of claim 14, wherein a top view shape of the bonding pad comprises at least one of:
an approximate circle shape,
an approximate rectangle shape,
an approximate hexagon shape, or
an approximate L-shape.
